(19) United States
(12) Patent Application Publication
(10) Pub. No.: US 2025/0022964 A1
(43) Pub. Date: Jan. 16, 2025

(54) SEMICONDUCTOR DEVICE AND DISPLAY DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP); Masahiro WATABE, Tokyo (JP)

(73) Assignee: Japan Display Inc., Tokyo (JP)

(21) Appl. No.: 18/760,532

(22) Filed: Jul. 1, 2024

(30) Foreign Application Priority Data
Jul. 12, 2023 (JP) 2023-114746

(51) Int. Cl. H01L 29/786; H01L 29/423

(52) U.S. Cl. CPC H01L 29/7869; H01L 29/42384; H01L 29/78633

(57) ABSTRACT

A semiconductor device comprises a first insulating layer, an oxide semiconductor layer having a polycrystalline structure on the first insulating layer, a gate insulating layer on the oxide semiconductor layer, a gate wiring on the gate insulating layer, and a second insulating layer on the gate wiring. The oxide semiconductor layer has a first region, a second region and a third region aligned toward a first direction. The first region overlaps the gate insulating layer and the gate wiring. The third region is in contact with the second insulating layer. A distance from a top surface of the second region to a top surface of the second insulating layer is longer than a distance from a top surface of the third region to the top surface of the second insulating layer.

### CROSS REFERENCE TO RELATED APPLICATIONS

This application claims the benefit of priority to Japanese Patent Application No. 2023-114746, filed on Jul. 12, 2023, the entire contents of which are incorporated herein by reference.

### FIELD

An embodiment of the present invention relates to a semiconductor device and a display device. Particularly, an embodiment of the present invention relates to a semiconductor device containing an oxide semiconductor and a display device using the semiconductor device containing an oxide semiconductor.

### BACKGROUND

In recent years, an oxide semiconductor, instead of amorphous silicon, polysilicon, and single-crystal silicon, has attracted attention as a constituent material of a semiconductor device. In particular, a thin film transistor using an oxide semiconductor as a channel has been developed as the semiconductor device containing an oxide semiconductor (see, for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The thin film transistor using an oxide semiconductor as a channel can be formed in a simple structure and low temperature process, similar to a semiconductor device using amorphous silicon as a channel. The thin film transistor using an oxide semiconductor as a channel is known to have a higher field-effect mobility than the thin film transistor using amorphous silicon as a channel.

### SUMMARY

A semiconductor device according to an embodiment of the present invention comprises a first insulating layer, an oxide semiconductor layer having a polycrystalline structure on the first insulating layer, a gate insulating layer on the oxide semiconductor layer, a gate wiring on the gate insulating layer, and a second insulating layer on the gate wiring. The oxide semiconductor layer has a first region, a second region and a third region aligned toward a first direction. The first region overlaps the gate insulating layer and the gate wiring. The third region is in contact with the second insulating layer. A distance from a top surface of the second region to a top surface of the second insulating layer is longer than a distance from a top surface of the third region to the top surface of the second insulating layer.

### BRIEF DESCRIPTION OF THE DRAWINGS

FIG. 1 is a schematic cross-sectional view showing a configuration of a semiconductor device according to an embodiment of the present invention.

FIG. 2 is a schematic plan view showing a configuration of a semiconductor device according to an embodiment of the present invention.

FIG. 3 is a schematic enlarged cross-sectional view showing a configuration of a semiconductor device according to an embodiment of the present invention.

FIG. 4A is a schematic cross-sectional view explaining a hydrogen blocking effect according to an embodiment of the present invention.

FIG. 4B is a schematic plan view explaining a hydrogen blocking effect according to an embodiment of the present invention.

FIG. 5 is a sequence diagram showing a method for manufacturing a semiconductor device according to an embodiment of the present invention.

FIG. 6 is a schematic cross-sectional view showing a method for manufacturing a semiconductor device according to an embodiment of the present invention.

FIG. 7 is a schematic cross-sectional view showing a method for manufacturing a semiconductor device according to an embodiment of the present invention.

FIG. 8 is a schematic cross-sectional view showing a method for manufacturing a semiconductor device according to an embodiment of the present invention.

FIG. 9 is a schematic cross-sectional view showing a method for manufacturing a semiconductor device according to an embodiment of the present invention.

FIG. 10 is a schematic cross-sectional view showing a method for manufacturing a semiconductor device according to an embodiment of the present invention.

FIG. 11 is a schematic cross-sectional view showing a method for manufacturing a semiconductor device according to an embodiment of the present invention.

FIG. 12 is a schematic cross-sectional view showing a method for manufacturing a semiconductor device according to an embodiment of the present invention.

FIG. 13 is a schematic cross-sectional view showing a method for manufacturing a semiconductor device according to an embodiment of the present invention.

FIG. 14 is a schematic cross-sectional view showing a method for manufacturing a semiconductor device according to an embodiment of the present invention.

FIG. 15 is a schematic cross-sectional view showing a method for manufacturing a semiconductor device according to an embodiment of the present invention.

FIG. 16 is a schematic cross-sectional view showing a method for manufacturing a semiconductor device according to an embodiment of the present invention.

FIG. 17 is a schematic cross-sectional view showing a method for manufacturing a semiconductor device according to an embodiment of the present invention.

FIG. 18 is a schematic cross-sectional view showing a configuration of a semiconductor device according to an embodiment of the present invention.

FIG. 19 is a sequence diagram showing a method for manufacturing a semiconductor device according to an embodiment of the present invention.

FIG. 20 is a sequence diagram showing a method for manufacturing a semiconductor device according to an embodiment of the present invention.

FIG. 21 is a schematic cross-sectional view showing a configuration of a semiconductor device according to an embodiment of the present invention.

FIG. 22 is a schematic cross-sectional view showing a configuration of a semiconductor device according to an embodiment of the present invention.

FIG. 23A is a schematic plan view showing a configuration of a semiconductor device according to an embodiment of the present invention.

FIG. 23B is a schematic plan view showing a configuration of metal oxide layer of a semiconductor device according to an embodiment of the present invention.

FIG. 24 is a sequence diagram showing a method for manufacturing a semiconductor device according to an embodiment of the present invention.

FIG. 25 is a schematic cross-sectional view showing a method for manufacturing a semiconductor device according to an embodiment of the present invention.

FIG. 26 is a schematic cross-sectional view showing a method for manufacturing a semiconductor device according to an embodiment of the present invention.

FIG. 27 is a schematic cross-sectional view showing a method for manufacturing a semiconductor device according to an embodiment of the present invention.

FIG. 28 is a schematic cross-sectional view showing a method for manufacturing a semiconductor device according to an embodiment of the present invention.

FIG. 29 is a sequence diagram showing a method for manufacturing a semiconductor device according to an embodiment of the present invention.

FIG. 30 is a schematic plan view showing an entire configuration of a display device according to an embodiment of the present invention.

FIG. 31 is a block diagram showing a circuit configuration of a display device according to an embodiment of the present invention.

FIG. 32 is a circuit diagram showing a configuration of a pixel circuit of a display device according to an embodiment of the present invention.

FIG. 33 is a schematic cross-sectional view showing a configuration of a pixel of a display device according to an embodiment of the present invention.

FIG. 34 is a schematic plan view of a pixel electrode and a common electrode of a pixel shown in FIG. 32.

FIG. 35 is a circuit diagram showing a pixel circuit of a display device according to an embodiment of the present invention.

FIG. 36 is a schematic cross-sectional view showing a configuration of a pixel of a display device according to an embodiment of the present invention.

FIG. 37 is a drawing-substitute photograph showing a cross-sectional structure of a semiconductor device according to an embodiment of the present invention.

FIG. 38 is a diagram showing electrical characteristics of a semiconductor device according to an embodiment of the present invention.

FIG. 39 is a graph showing a relationship between an amount of over-etching during etching of a gate insulating layer and a length of an LDD region.

FIG. 40 is a graph showing a relationship between an amount of over-etching during etching of a gate insulating layer and a field-effect mobility.

FIG. 41 is a graph showing a relationship between a length of an LDD region and a field-effect mobility.

### DESCRIPTION OF EMBODIMENTS

In a conventional thin film transistor containing an oxide semiconductor, when a channel length decreases, a threshold voltage indicating a switching property may shift in a negative direction or a variation in the threshold voltage may increase. For this reason, the conventional thin film transistor containing an oxide semiconductor has low flexibility when designing the channel length in order to reduce the size, and the application may be limited.

An object of the present invention is to improve the reliability of the semiconductor device containing an oxide semiconductor.

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the width, thickness, shape, and the like of each part in comparison with an actual embodiment. However, the illustrated shapes are merely examples, and do not limit the interpretation of the present invention. In the present specification and the drawings, the same reference signs are given to elements similar to those described above with respect to the above-described drawings, and detailed description thereof may be omitted as appropriate.

In the embodiments of the present invention, a direction from a substrate toward an oxide semiconductor layer is referred to as “on” or “above”. Conversely, a direction from the oxide semiconductor layer to the substrate is referred to as “under” or “below”. In this way, for convenience of explanation, the phrase “above” or “below” is used for description purposes, but for example, the substrate and the oxide semiconductor layer may be arranged so that the vertical relationship is reversed from that shown in the drawings. In the following explanation, for example, the expression “an oxide semiconductor layer on a substrate” merely describes the vertical relationship between the substrate and the oxide semiconductor layer as described above, and another member may be arranged between the substrate and the oxide semiconductor layer. “Above” or “below” refers to a stacking order in which a plurality of layers is stacked, and may be a positional relationship in which a transistor and a pixel electrode do not overlap in a plan view when expressed as “pixel electrode above the transistor”. On the other hand, the expression “pixel electrode vertically above the transistor” means a positional relationship in which the transistor and the pixel electrode overlap in a plan view.

“Display device” refers to a structure that displays an image using an electro-optic layer. For example, the term display device may refer to a display panel that includes the electro-optic layer, or may refer to a structure with other optical members (for example, a polarized member, a backlight, a touch panel, and the like) attached to a display cell. The “electro-optical layer” may include a liquid crystal layer, an electroluminescent (EL) layer, an electrochromic (EC) layer, and an electrophoretic layer, unless there is no technical contradiction. Therefore, in the embodiment described later, a liquid crystal display device including a liquid crystal layer and an organic EL display device including an organic EL layer are exemplified as the display device, but the structure according to the embodiment can be applied to a display device including the other electro-optical layers described above.

In the present specification, expressions “a includes A, B, or C,” “a includes any of A, B, and C,” “a includes one selected from a group consisting of A, B, and C,” and the like do not exclude the case where a includes a plurality of combinations of A to C unless otherwise indicated. Furthermore, these expressions do not exclude the case where a includes other elements.

In the present specification, “same” includes, in addition to being completely identical, also the case where elements are substantially identical. “Substantially the same” refers to the case that falls within a range of small differences that are not completely identical but can be regarded as identical, for example, within an error of ±5% (preferably ±3%).

### First Embodiment

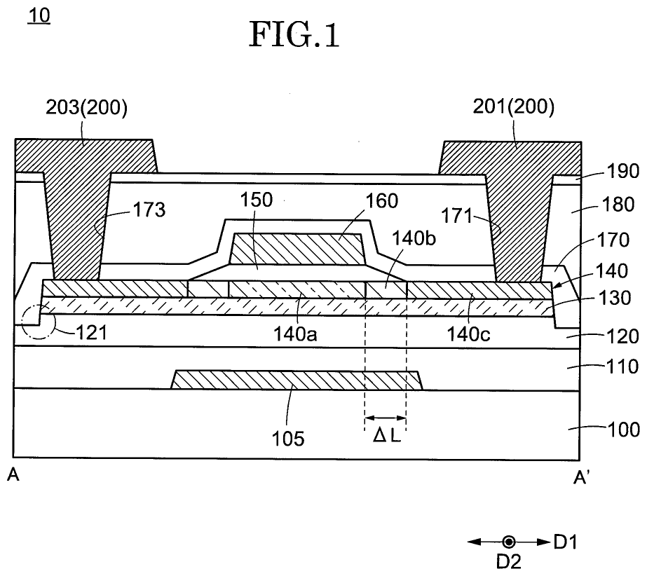

A semiconductor device according to an embodiment of the present invention will be described with reference to FIG. 1 to FIG. 17 by exemplifying a thin film transistor. For example, a semiconductor device described later may be an integrated circuit (IC) such as a micro-processing unit (MPU) or a thin film transistor used in a memory circuit, in addition to a thin film transistor used in a display device.

### [Configuration of Semiconductor Device]

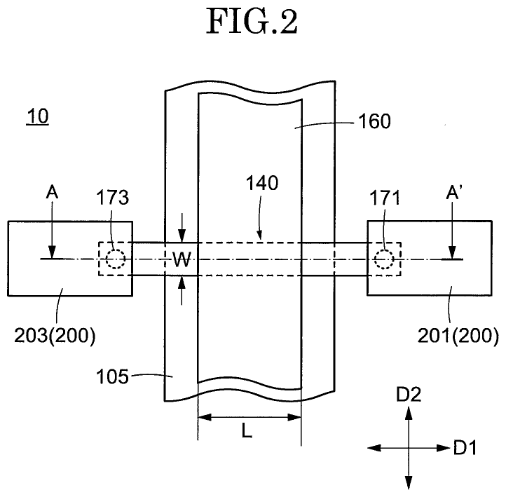

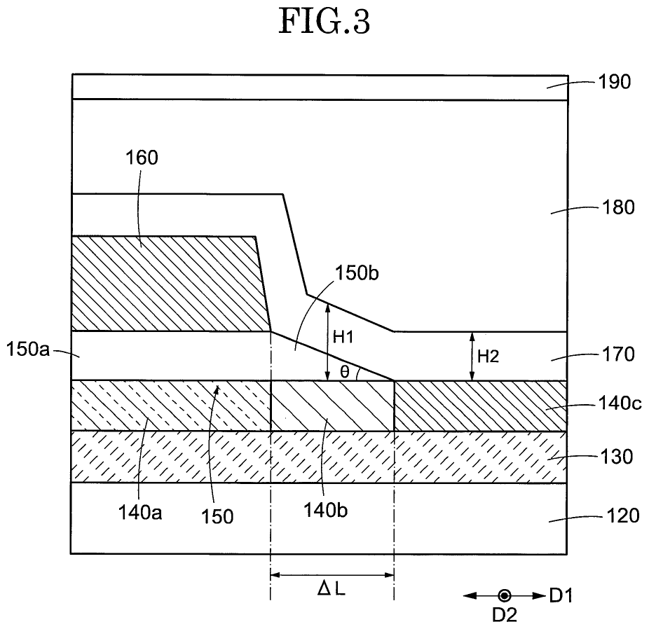

The configuration of the semiconductor device 10 according to an embodiment of the present invention will be described with reference to FIG. 1 to FIG. 3. FIG. 1 is a schematic cross-sectional view showing a configuration of a semiconductor device 10 according to an embodiment of the present invention. FIG. 2 is a schematic plan view showing a configuration of the semiconductor device 10 according to an embodiment of the present invention. FIG. 3 is a schematic enlarged cross-sectional view showing a configuration of the semiconductor device 10 according to an embodiment of the present invention. Specifically, FIG. 1 corresponds to a cross-sectional view cut along a dashed-dotted line indicated by A-A′ shown in FIG. 2. FIG. 3 corresponds to an enlarged cross-sectional view of a vicinity of an end portion of a gate insulating layer 150 shown in FIG. 1.

First, a cross-sectional configuration of the semiconductor device 10 will be described with reference to FIG. 1. As shown in FIG. 1, the semiconductor device 10 is arranged above a substrate 100. The semiconductor device 10 includes a conductive layer 105, insulating layers 110 and 120, a metal oxide layer 130, an oxide semiconductor layer 140, a gate insulating layer 150, a gate wiring 160, insulating layers 170 to 190, a source wiring 201, and a drain wiring 203. If the source wiring 201 and the drain wiring 203 are not specifically distinguished from each other, they may be collectively referred to as a source/drain wiring 200.

In the present specification, “wiring” refers to a conductive layer that electrically connects elements, circuits, or elements and circuits. The wiring may also function as an electrode. For example, part of the gate wiring 160 that overlaps the oxide semiconductor layer 140 functions as a gate electrode. In addition, part of the source wiring 201 and the drain wiring 203 connected to the oxide semiconductor layer 140 functions as a source electrode and a drain electrode, respectively.

The conductive layer 105 is arranged on the substrate 100. The conductive layer 105 has a function as a light-shielding film for the oxide semiconductor layer 140.

The insulating layers 110 and 120 are arranged on the substrate 100 and the conductive layer 105. The insulating layer 110 functions as a barrier film that shields impurities that diffuse from the substrate 100 toward the oxide semiconductor layer 140. The insulating layer 120 functions as a base of the metal oxide layer 130 arranged above.

In the embodiment shown in FIG. 1, an upper surface of the insulating layer 120 and a lower surface of the metal oxide layer 130 are in contact with each other below the metal oxide layer 130. However, the upper surface of the insulating layer 120 is positioned below the lower surface of the metal oxide layer 130 in a region where the insulating layer 120 does not overlap the metal oxide layer 130. That is, in the example shown in FIG. 1, a step 121 is formed in the insulating layer 120 in a vicinity of an end portion of the metal oxide layer 130. This is because when etching the gate insulating layer 150, the upper surface of the insulating layer 120 in the region not overlapping the metal oxide layer 130 and the oxide semiconductor layer 140 is etched. However, the step 121 may not be formed depending on a condition of the etching of the gate insulating layer 150. This point will be described later.

The metal oxide layer 130 is arranged on the insulating layer 120. The metal oxide layer 130 is in contact with the insulating layer 120. The metal oxide layer 130 is a layer containing metal oxide containing aluminum as a main component, and has a function as a gas barrier film for shielding a gas such as oxygen or hydrogen.

The oxide semiconductor layer 140 is arranged on the metal oxide layer 130. The oxide semiconductor layer 140 is in contact with the metal oxide layer 130. In the present embodiment, the metal oxide layer 130 and the oxide semiconductor layer 140 have the same pattern shape. That is, in the cross-sectional view, the end portion of the metal oxide layer 130 and the end portion of the oxide semiconductor layer 140 are substantially the same. In the present embodiment, although a configuration in which the metal oxide layer 130 is in contact with the insulating layer 120 and the oxide semiconductor layer 140 is in contact with the metal oxide layer 130 is exemplified, the configuration is not limited to this configuration. Another layer may be arranged between the metal oxide layer 130 and the oxide semiconductor layer 140.

In addition, although a side surface of the metal oxide layer 130 and a side surface of the oxide semiconductor layer 140 are arranged substantially in a straight-line in FIG. 1, the configuration is not limited to this. An angle of the side surface of the metal oxide layer 130 with respect to the main surface of the substrate 100 may be different from an angle of the side surface of the oxide semiconductor layer 140. The cross-sectional shapes of the side surfaces of at least one of the metal oxide layer 130 and the oxide semiconductor layer 140 may be curved.

As shown in FIG. 1, the oxide semiconductor layer 140 has a channel region 140a, an LDD region 140b and a conductive region 140c arranged in a first direction. The channel region 140a is a region of the oxide semiconductor layer 140 that overlaps the gate wiring 160, and functions as a channel of the transistor. The LDD region 140b is a region that is lower in resistance than the channel region and functions as a resistance component for carrier mobility. The conductive region 140c is a region called a source region or a drain region and functions as a conductive layer connected to the source wiring 201 or the drain wiring 203. The conductive region 140c is a region that is lower in resistance than the LDD region 140b.

Although details will be described later, the LDD region 140b is considered to function in the same way as a so-called LDD (Light Doped Drain) region for carrier mobility. That is, the LDD region 140b acts as a resistance component for carrier mobility. Therefore, in the present specification, for convenience of explanation, a region between the channel region 140a and the conductive region 140c is referred to as the LDD region.

The gate insulating layer 150 is arranged on the oxide semiconductor layer 140. Specifically, the gate insulating layer 150 has a region overlapping the gate wiring 160 (an overlapping region 150a in FIG. 3) and a region not overlapping the gate wiring 160 (a non-overlapping region 150b in FIG. 3). That is, a width of the gate insulating layer 150 in the first direction (direction D1) is wider than a width of the gate wiring 160. This point will be described later with reference to FIG. 3. The LDD region 140b of the oxide semiconductor layer 140 is a region positioned vertically below the non-overlapping region 150b of the gate insulating layer 150 described above. In the example shown in FIG. 1, a length (width) of the LDD region 140b in the first direction is ΔL.

Since the gate insulating layer 150 is removed by etching leaving part of the periphery of the gate wiring 160, part of the oxide semiconductor layer 140 is not covered with the gate insulating layer 150. In other words, a part of the oxide semiconductor layer 140 is exposed from the gate insulating layer 150. The gate insulating layer 150 has a function as a gate insulating layer for a top gate (gate wiring 160).

The gate wiring 160 faces the oxide semiconductor layer 140 via the gate insulating layer 150. That is, the gate insulating layer 150 is arranged between the oxide semiconductor layer 140 and the gate wiring 160. The gate insulating layer 150 is in contact with the oxide semiconductor layer 140. The gate wiring 160 serves as the top gate of the semiconductor device 10 and a light-shielding film for the oxide semiconductor layer 140.

The insulating layers 170 to 190 are arranged on the gate insulating layer 150 and the gate wiring 160. In the present embodiment, a stacked structure composed of the insulating layers 170 to 190 may be referred to as a passivation layer. The insulating layers 170 to 190 insulate the gate wiring 160 and the source/drain wiring 200. Arranging the insulating layers 170 to 190 makes it possible to reduce the parasitic capacitance between the gate wiring 160 and the source/drain wiring 200.

In the present embodiment, a silicon oxide layer, a silicon nitride layer, and a silicon oxide layer are used as the insulating layer 170, the insulating layer 180, and the insulating layer 190, respectively. The component of the insulating layers 170 to 190 is preferably an insulating layer containing at least one layer of hydrogen, but not limited to this example as described below. In the present embodiment, a silicon oxide layer is used as the insulating layer 190, so that it functions as an etching stopper when patterning the source wiring 201 and the drain wiring 203.

As shown in FIG. 1, the insulating layer 170 forming part of the passivation layer is in contact with the gate wiring 160, the gate insulating layer 150 (specifically, the region of the gate insulating layer 150 not overlapping the gate wiring 160), and the oxide semiconductor layer 140. Openings 171 and 173 reaching the oxide semiconductor layer 140 are arranged in the insulating layers 170 to 190.

The source wiring 201 is arranged inside the opening 171 arranged in the insulating layers 170 to 190. The source wiring 201 is in contact with the oxide semiconductor layer 140 (specifically, the conductive region 140c) at the bottom of the opening 171. The drain wiring 203 is arranged inside the opening 173 arranged in the insulating layers 170 and 180. The drain wiring 203 is in contact with the oxide semiconductor layer 140 (specifically, the conductive region 140c) at the bottom of the opening 173.

An operation of the semiconductor device 10 is controlled mainly by a gate voltage supplied to the gate wiring 160. An auxiliary voltage may be supplied to the conductive layer 105. That is, the conductive layer 105 may function as a gate wiring by supplying an auxiliary voltage. However, it is not limited to this example, and the conductive layer 105 may be used merely as a light-shielding film. In the case where the conductive layer 105 is simply used as a light-shielding film, the conductive layer 105 may be floating without being supplied with a specific voltage.

In the present embodiment, although a top-gate transistor in which the gate wiring 160 is arranged above the oxide semiconductor layer 140 is exemplified as the semiconductor device 10, the configuration is not limited to this. For example, a dual gate transistor using the conductive layer 105 as the gate wiring can be used as the semiconductor device 10 in addition to the gate wiring 160. In the case where the conductive layer 105 is used as the gate wiring, the insulating layers 110 and 120 function as the gate insulating layer. However, the above configuration is merely one embodiment, and the present invention is not limited to the above configuration.

Next, a planar structure of the semiconductor device 10 will be described with reference to FIG. 2. As shown in FIG. 2, the first direction (direction D1) is a direction connecting the source wiring 201 and the drain wiring 203, and corresponds to a direction in which carriers move. A length of the oxide semiconductor layer 140 in the first direction of the channel region 140a is a channel length (L), and a length of the channel region 140a in a second direction (direction D2) is a channel width (W). In addition, the second direction is a direction intersecting the first direction. In the present embodiment, although the second direction indicates a direction orthogonal to the first direction, the first direction may not be orthogonal to the second direction depending on the layout of the oxide semiconductor layer 140.

As described above, the metal oxide layer 130 and the oxide semiconductor layer 140 have the same pattern shape in the present embodiment. Therefore, although not illustrated in FIG. 2, the metal oxide layer 130 having the same shape is arranged below the oxide semiconductor layer 140. However, the present invention is not limited to the example shown in FIG. 2, and part of the oxide semiconductor layer 140 may not be in contact with the metal oxide layer 130. For example, all of the lower surface of the channel region 140a may be covered with the metal oxide layer 130, and all or part of the lower surface of the LDD region 140b and the conductive region 140c may not be covered with the metal oxide layer 130. That is, all or part of the lower surface of the LDD region 140b and the conductive region 140c may not be in contact with the metal oxide layer 130. Conversely, all or part of the lower surface of the channel region 140a may not be covered with the metal oxide layer 130, and other regions may be in contact with the metal oxide layer 130.

In the present embodiment, a width of the conductive layer 105 is wider than the width of the gate wiring 160 in the first direction. The reason for this configuration is to effectively prevent external light from entering the channel region 140a. However, it is not limited to this example, and the width of the conductive layer 105 may be the same as the width of the gate wiring 160.

Although a configuration in which the source/drain wiring 200 does not overlap the gate wiring 160 and the conductive layer 105 is shown in FIG. 2 in a plan view, the present invention is not limited to this configuration. For example, in a plan view, the source/drain wiring 200 may overlap at least one of the conductive layer 105 and the gate wiring 160. The above configuration is merely an embodiment, and the present invention is not limited to the above configuration.

### [Material of Each Layer of Semiconductor Device]

The substrate 100 may support each layer of the semiconductor device 10. For example, a rigid substrate having light transmittance such as a glass substrate, a quartz substrate, or a sapphire substrate can be used as the substrate 100. In addition, a rigid substrate having no light transmittance such as a silicone substrate can also be used as the substrate. Further, a flexible substrate having light transmittance such as a polyimide resin substrate, an acryl resin substrate, a siloxane resin substrate, or a fluororesin substrate can be used as the substrate. In order to improve the heat resistance of the substrate 100, impurities may be introduced into the resin substrate. In addition, a substrate in which a silicon oxide film or a silicon nitride film is formed on the above-described rigid substrate or flexible substrate can also be used as the substrate 100.

The conductive layer 105 may reflect or absorb external light. As described above, since the conductive layer 105 has an area larger than the channel region 140a of the oxide semiconductor layer 140, external light incident on the channel region 140a can be shielded. For example, aluminum (Al), copper (Cu), titanium (Ti), molybdenum (Mo), or tungsten (W), or an alloy or a compound thereof can be used as the conductive layer 105. In addition, if no electrical conductivity is required, a resin layer composed of a black resin or the like may be used instead of the conductive layer 105. The conductive layer 105 may have a single-layer structure or a stacked structure.

The insulating layers 110, 120, and 170 to 190 have a function of preventing impurities from diffusing into the oxide semiconductor layer 140. The insulating layers 110, 120, and 170 to 190 may have a single-layer structure or a stacked structure. Examples of the insulating layers 110, 120, and 170 to 190 include silicon oxide (SiOₓ), silicon oxynitride (SiOₓ N_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), and aluminum nitride (AlNₓ). In this case, silicon oxynitride (SiOₓN_{y}) and aluminum oxynitride (AlOₓN_{y}) are a silicon compound and aluminum compound containing a smaller proportion (x>y) of nitrogen (N) than oxygen (O), respectively. In addition, silicon nitride oxide (SiNₓO_{y}) and aluminum nitride oxide (AlNₓO_{y}) are a silicon compound and aluminum compound containing a smaller proportion (x>y) of oxygen than nitrogen. In the present embodiment, silicon nitride (SiNₓ) is used as the insulating layers 110 and 180, and silicon oxide (SiOₓ) is used as the insulating layers 120, 170, and 190.

Metal oxide containing aluminum as a main component is used as the metal oxide layer 130. For example, an inorganic insulating layer such as aluminum oxide (AlOₓ), aluminum oxynitride (AlOₓ N_{y}), aluminum nitride oxide (AlNₓO_{y}), or aluminum nitride (AlNₓ) is used as the metal oxide layer 130. The expression “metal oxide layer containing aluminum as a main component” means that the proportion of aluminum contained in the metal oxide layer 130 is 1% or more of the entire metal oxide layer 130. The proportion of aluminum contained in the metal oxide layer 130 may be 5% or more and 70% or less, 10% or more and 60% or less, or 30% or more and 50% or less of the entire metal oxide layer 130. The ratio may be a mass ratio or a weight ratio.

In the present embodiment, the oxide semiconductor layer 140 has a polycrystalline structure. That is, the oxide semiconductor layer 140 of the present embodiment is composed of an oxide semiconductor formed using a Poly-OS technique. The Poly-OS technique refers to a technique of forming an oxide semiconductor layer with a polycrystalline structure. Metal oxide having semiconductor properties can be used as the oxide semiconductor layer 140. For example, an oxide semiconductor containing two or more metals including indium (In) is used as the oxide semiconductor layer 140. The proportion of indium to the entire oxide semiconductor layer 140 is 50% or more. Gallium (Ga), zinc (Zn), aluminum (Al), hafnium (Hf), yttrium (Y), zirconia (Zr), and lanthanoids are used as the oxide semiconductor layer 140, in addition to indium. Elements other than those described above may be used as the oxide semiconductor layer 140.

Since the proportion of indium is 50% or more in the oxide semiconductor layer 140 of the present embodiment, oxygen vacancies are likely to be formed. On the other hand, oxygen vacancies are less likely to be formed in an oxide semiconductor with crystallinity than in an amorphous oxide semiconductor. Therefore, the oxide semiconductor layer 140 has an advantage that oxygen vacancies are less likely to be formed even though the proportion of indium is 50% or more.

The gate insulating layer 150 includes an oxide having insulating properties. Specifically, silicon oxide (SiOₓ), silicon oxynitride (SiOₓN_{y}), aluminum oxide (AlOₓ), aluminum oxynitride (AlOₓN_{y}), or the like can be used as the gate insulating layer 150. The gate insulating layer 150 preferably has a composition close to the stoichiometric ratio. In addition, the gate insulating layer 150 is preferably less defective. For example, an oxide in which no defects are observed when evaluated by an electron-spin resonance method (ESR) may be used as the gate insulating layer 150.

The gate wiring 160, the source wiring 201, and the drain wiring 203 have conductivity. For example, copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or an alloy or compound thereof can be used as each of the gate wiring 160, the source wiring 201, and the drain wiring 203. Each of the gate wiring 160, the source wiring 201, and the drain wiring 203 may be a single-layer structure or a stacked structure.

### [Configuration in the Vicinity of End Portion of Gate Wiring]

A configuration in the vicinity of an end portion of the gate wiring 160 will be described with reference to FIG. 3. As shown in FIG. 3, the oxide semiconductor layer 140 is divided into the channel region 140a, the LDD region 140b, and the conductive region 140c. The channel region 140a is a region of the oxide semiconductor layer 140 positioned vertically below the gate wiring 160 and in contact with the gate insulating layer 150. The conductive region 140c is a region of the oxide semiconductor layer 140 in contact with the insulating layer 170. The LDD region 140b is a region positioned between the channel region 140a and the conductive region 140c. Specifically, the LDD region 140b is a region not overlapping the gate wiring 160 and is in contact with the gate insulating layer 150.

In this case, the gate insulating layer 150 is divided into the overlapping region 150a overlapping the gate wiring 160 and the non-overlapping region 150b not overlapping the gate wiring 160. That is, it can be said that the channel region 140a is a region in contact with the overlapping region 150a of the gate insulating layer 150. In addition, it can be said that the LDD region 140b is a region in contact with the non-overlapping region 150b of the gate insulating layer 150.

Although details will be described later, in the present embodiment, the gate wiring 160 is patterned, and then the gate insulating layer 150 is etched using a resist mask used for etching the gate wiring 160. In this case, an end portion of the gate insulating layer 150 is processed into a tapered shape by using retreat of the resist mask (etching in the first direction) by etching. That is, as shown in FIG. 3, an upper surface of the non-overlapping region 150b is inclined with respect to an upper surface of the oxide semiconductor layer 140 (specifically, the LDD region 140b). In the present embodiment, an inclination angle (also referred to as a taper angle) of the upper surface of the non-overlapping region 150b with respect to the upper surface of the oxide semiconductor layer 140 is defined as θ. Although the inclination angle (θ) is determined by a thickness of the gate insulating layer 150 and the retreat amount of the resist mask, the inclination angle (θ) is preferably set to be 5° or more and 20° or less.

As described above, in the semiconductor device 10 of the present embodiment, the upper surface of the non-overlapping region 150b is an inclined surface. Therefore, part of the insulating layer 170 positioned above the non-overlapping region 150b covering the upper surface of the gate wiring 160, the non-overlapping region 150b, and the conductive region 140c is inclined along the lower inclined surface of the non-overlapping region 150b. That is, an upper surface of the insulating layer 170 positioned above the non-overlapping region 150b is inclined with respect to the upper surface of the oxide semiconductor layer 140 in a range of 5° or more and 20° or less. Therefore, as shown in FIG. 3, a distance H1 from an upper surface of the LDD region 140b to the upper surface of the insulating layer 170 is longer than a distance H2 from an upper surface of the conductive region 140c to the upper surface of the insulating layer 170. In this case, the terms “distance H1” and “distance H2” refer to distances in a normal direction to the upper surface of the oxide semiconductor layer 140.

As described above, the gate insulating layer 150 (specifically, the non-overlapping region 150b) and the insulating layer 170 are stacked above the LDD region 140b, and the gate insulating layer 150 has a tapered shape. Therefore, the diffusion of hydrogen into the oxide semiconductor layer 140 is suppressed in the process of reducing the resistance of the oxide semiconductor layer 140 using hydrogen (a process of forming the conductive region 140c), which will be described later. The LDD region 140b is formed between the channel region 140a and the conductive region 140c by suppressing the diffusion of hydrogen.

In addition, as shown in FIG. 3, a length (width) of the non-overlapping region 150b in the first direction corresponds to a length (width) of the LDD region 140b in the first direction. In FIG. 3, the length of the LDD region 140b in the first direction is represented as ΔL. The length of the non-overlapping region 150b in the first direction is determined by the retreat amount of the resist mask described above. In the present embodiment, since the etching of the gate insulating layer 150 is continued until at least the conductive region 140c of the oxide semiconductor layer 140 is exposed, the length of the non-overlapping region 150b is determined according to the time required for the conductive region 140c to be exposed from the beginning of the etching of the gate insulating layer 150. In addition, the length of the non-overlapping region 150b can be controlled by the time of the etching process after the conductive region 140c is exposed (the time of over-etching). In the present embodiment, the length of the non-overlapping region 150b in the first direction, that is, the length of the LDD region 140b in the first direction is controlled to be 0.3 μm or more (preferably, 0.3 μm or more and 1.0 μm or less). As described above, since the LDD region 140b functions as a resistance component for carrier mobility, if it is too long, it may lead to degradation of the electrical characteristics of the semiconductor device 10. Therefore, the length of the LDD region 140b is preferably 1.0 μm or less. In the case where the length of the LDD region 140b is too short, the gate insulating layer 150 may be poorly etched and the conductive region 140c may not be completely exposed. This may lead to malfunction of the semiconductor device 10, such as a poor connection between the conductive region 140c and the source/drain wiring 200. Further, the shorter the length of the LDD region 140b, the lower the drain breakdown voltage of the semiconductor device 10. Therefore, also from the viewpoint of improving reliability, the length of the LDD region 140b is preferably 0.3 μm or more.

In addition, as will be described later, the present inventors have conducted experiments on the case where the thickness of the gate insulating layer 150 is 100 nm, and have concluded that it is preferable to set the length of the LDD region 140b to 0.3 μm or more. However, the preferable range of the length of the LDD region 140b is not limited to the case where the thickness of the gate insulating layer 150 is 100 nm.

For example, in the case where the thickness of the gate insulating layer 150 is 100 nm or more, the length of the non-overlapping region 150b (that is, the LDD region 140b) is necessarily 0.3 μm or more. In addition, in the case where the thickness of the gate insulating layer 150 is less than 100 nm, the length of the non-overlapping region 150b may be less than 0.3 μm when the conductive region 140c is completely exposed. However, when the thickness of the gate insulating layer 150 is reduced, a current flowing through the channel region 140a is increased, and therefore, it is preferable to improve the drain breakdown voltage. Therefore, in order to improve the reliability of the semiconductor device 10 in which the thickness of the gate insulating layer 150 is less than 100 nm, it is preferable to continue the etching process of the gate insulating layer 150 until the non-overlapping region 150b becomes 0.3 μm or more, regardless of whether the conductive region 140c is exposed.

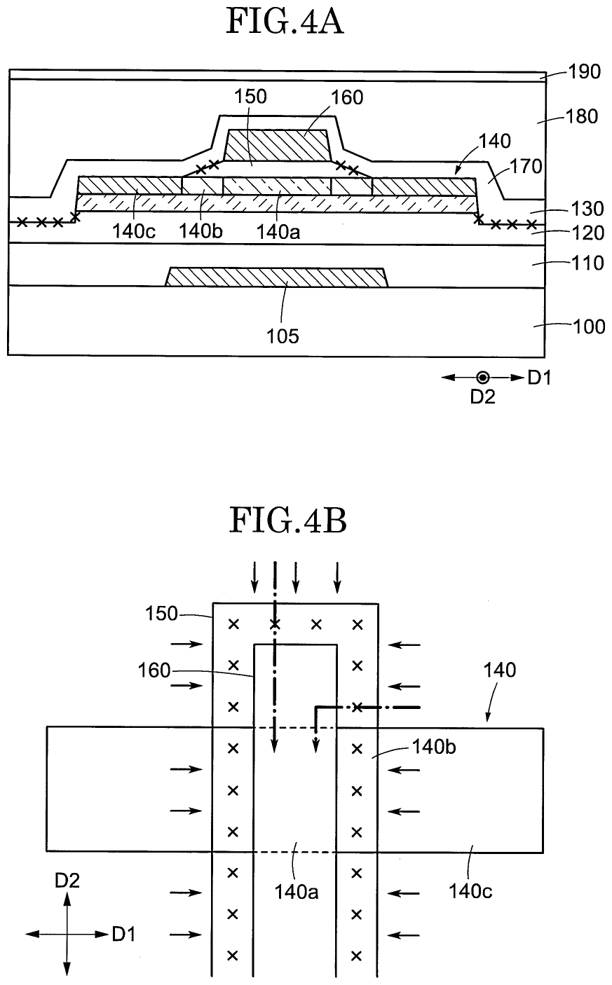

As described above, the non-hydrogen overlapping region 150b of the gate insulating layer 150 has a function of suppressing the diffusion of hydrogen from above. This point will be described with reference to FIG. 4.

FIG. 4A is a schematic cross-sectional view explaining a hydrogen blocking effect according to an embodiment of the present invention. FIG. 4B is a schematic plan view explaining a hydrogen blocking effect according to an embodiment of the present invention.

As will be described later, in the semiconductor device 10 of the present embodiment, resistance of the oxide semiconductor layer 140 is reduced by using hydrogen contained in the insulating layer 180 containing silicon nitride. Specifically, the conductive region 140c is formed by diffusing hydrogen into part of the oxide semiconductor layer 140. In this process, when the insulating layer 180 containing silicon nitride is deposited, hydrogen contained in the insulating layer 180 diffuses downward, and hydrogen is supplied to part of the oxide semiconductor layer 140. In the region to which hydrogen is supplied, oxygen contained in the region is reduced to form oxygen vacancies. Hydrogen is trapped in the oxygen vacancies formed to form a donor level. As a result, the resistance of part of the oxide semiconductor layer 140 to which hydrogen is supplied is reduced and becomes the conductive region 140c.

In this case, as shown in FIG. 4A, it is considered that defects generated when the gate insulating layer 150 is etched are present on the upper surface of the non-overlapping region 150b of the gate insulating layer 150 and the upper surface of the insulating layer 120, and hydrogen is trapped in the defects. That is, the upper surface of the gate insulating layer 150 in the non-overlapping region 150b and the upper surface of the insulating layer 120 function as a barrier layer that suppresses diffusion of hydrogen. Therefore, the LDD region 140b has a relatively lower resistance diffusivity than the conductive region 140c, resulting in a higher resistance region than the conductive region 140c. In addition, since almost no hydrogen diffuses into the channel region 140a, the channel region 140a can maintain its function as a semiconductor. In addition, the defects formed on the upper surface and the side surface of the insulating layer 120 (the side surface of the step 121 shown in FIG. 1) have a function of preventing hydrogen from diffusing downward into the oxide semiconductor layer 140. As described above, in the semiconductor device 10 of the present embodiment, since part of the gate insulating layer 150 does not overlap the gate wiring 160, the channel region 140a, the LDD region 140b, and the conductive region 140c can be formed in the oxide semiconductor layer 140 through a single hydrogen diffusion process.

Further, the non-overlapping region 150b of the gate insulating layer 150 is useful in suppressing the diffusion of hydrogen below the gate wiring 160. As shown in FIG. 4B, the gate wiring 160 has a region not overlapping the oxide semiconductor layer 140. If the non-overlapping region 150b of the gate insulating layer 150 is not present, the insulating layers 170 and 180 would be adjacent to the end portion of the gate wiring 160. Therefore, hydrogen may easily diffuse from the end portion of the gate wiring 160 toward below the gate wiring 160, and the diffused hydrogen may diffuse below the gate wiring 160 and reach the channel region 140a.

On the other hand, in the present embodiment, as shown in FIG. 4B, there is the non-overlapping region 150b around the gate wiring 160. In other words, the gate wiring 160 is surrounded by the non-overlapping region 150b of the gate insulating layer 150 in a plan view. Therefore, even if hydrogen is diffused from all directions, hydrogen is captured by the defects formed on the inclined surface of the non-overlapping region 150b as described above, so that the diffusion of hydrogen into the oxide semiconductor layer 140 can be suppressed. Although not shown in FIG. 4B, the upper surface of the insulating layer 120 is in contact with the lower surface of the insulating layer 170 around the oxide semiconductor layer 140 and around the gate insulating layer 150 (specifically, the non-overlapping region 150b). In other words, defects that capture hydrogen are formed so as to surround the oxide semiconductor layer 140 in the condition shown in FIG. 4B.

According to the present embodiment, the diffusion of hydrogen into the channel region 140a can be effectively suppressed during the process of forming the conductive region 140c in the oxide semiconductor layer 140 (the process of reducing the resistance of the oxide semiconductor layer 140 by the diffusion of hydrogen). In addition, a moderately hydrogen-diffused low resistance region (the LDD region 140b) can be formed between the channel region 140a and the conductive region 140c (that is, vertically below the non-overlapping region 150b). Such an LDD region 140b serves as a resistance component for carrier mobility, so that it has a function of improving the drain breakdown voltage. In the present embodiment, since the non-overlapping region 150b has a tapered shape, a concentration of hydrogen in the LDD region 140b increases from the channel region 140a towards the conductive region 140c. In other words, it can be said that the resistance value of the LDD region 140b decreases from the channel region 140a towards the conductive region 140c.

In the semiconductor device 10 of the present embodiment having the above-described structure, the diffusion of hydrogen directly under the gate wiring 160 is suppressed, and the semiconductor properties of the channel region 140a are maintained in the process of forming the conductive region 140c (the process of reducing the resistance of the oxide semiconductor layer 140). Therefore, the semiconductor device 10 exhibits excellent electrical characteristics even when the channel length is 2 μm or less (preferably 1 μm or less), without shifting the threshold voltage in the negative direction. Furthermore, since the semiconductor device 10 has the LDD region 140b between the channel region 140a and the conductive region 140c, it is highly reliable by improving the drain breakdown voltage.

### [Method for Manufacturing Semiconductor Device]

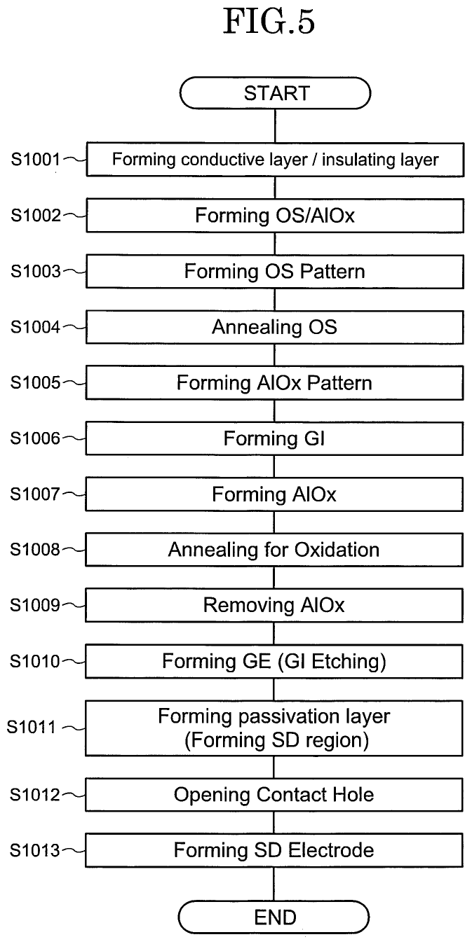

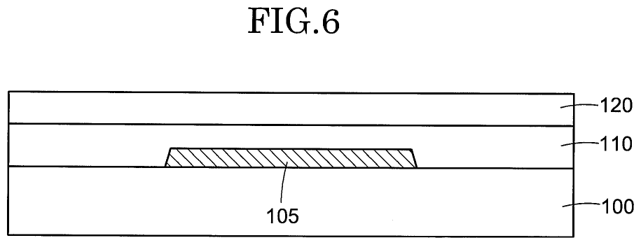

A method for manufacturing the semiconductor device 10 according to an embodiment of the present invention will be described with reference to FIG. 5 to FIG. 17. FIG. 5 is a sequence diagram showing a method for manufacturing the semiconductor device 10 according to an embodiment of the present invention. FIG. 6 to FIG. 17 are schematic cross-sectional views showing a method for manufacturing the semiconductor device 10 according to an embodiment of the present invention.

As shown in FIG. 5 and FIG. 6, the conductive layer 105 is formed as a light-shielding layer on the substrate 100, and the insulating layers 110 and 120 are formed on the conductive layer 105 (step S1001 of FIG. 5). For example, a silicon nitride layer is formed as the insulating layer 110. For example, a silicon oxide layer is formed as the insulating layer 120. The insulating layers 110 and 120 are formed by a CVD (Chemical Vapor Deposition) method. In the present specification, performing film formation on a substrate by a method such as a sputtering method or a CVD method is expressed as “forming a thin film”, but is used in the same sense as the expression “depositing a thin film”.

For example, using a silicon nitride layer as the insulating layer 110 enables the insulating layer 110 to block impurities that diffuse from the substrate 100 toward the oxide semiconductor layer 140. The silicon oxide layer used as the insulating layer 120 may include silicon oxide having a physical property of releasing oxygen by heat treatment.

In the present embodiment, when forming the insulating layers 110 and 120, the deposition temperature is set to 350° C. In particular, the oxygen content of the insulating layer 120 (that is, the silicon oxide layer) can be increased by setting the deposition temperature to be relatively low. As will be described later, increasing the amount of oxygen contained in the insulating layer 120 makes it possible to reduce the amount of hydrogen diffused into the oxide semiconductor layer 140. In addition, the deposition temperatures of the insulating layers 110 and 120 may be set to 250° C. or higher and 500° C. or lower (preferably 300° C. or higher and 450° C. or lower, and more preferably 325° C. or higher and 400° C. or lower).

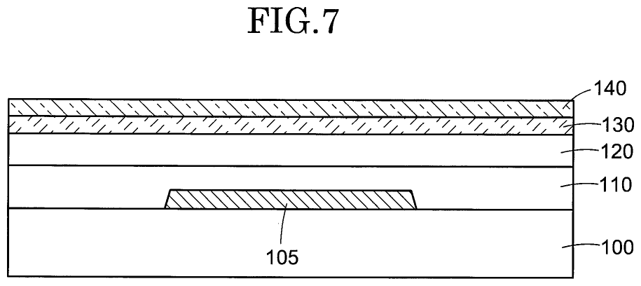

Next, as shown in FIG. 5 and FIG. 7, the metal oxide layer 130 and the oxide semiconductor layer 140 are formed on the insulating layer 120 (step S1002 of FIG. 5). In the present embodiment, the metal oxide layer 130 and the oxide semiconductor layer 140 are formed by a sputtering method. In particular, the oxide semiconductor layer 140 is formed by sputtering using a target formed of an oxide semiconductor with crystallinity.

For example, a thickness of the metal oxide layer 130 is 1 nm or more and 10 nm or less, 1 nm or more and 4 nm or less, or 1 nm or more and 3 nm or less. In the present embodiment, the thickness of the metal oxide layer 130 is 3 nm. In the present embodiment, an oxide containing aluminum as a main component (specifically, aluminum oxide) is used as the metal oxide layer 130. Aluminum oxide has a high barrier property against gas.

In the present embodiment, the aluminum oxide used as the metal oxide layer 130 blocks hydrogen and oxygen released from the insulating layer 120 and suppresses the released hydrogen and oxygen from reaching the oxide semiconductor layer 140.

In the oxide semiconductor layer 140 of the present embodiment, since the proportion of indium is 50% or more as described above, the semiconductor device 10 with high mobility can be realized, but oxygen is easily reduced, and oxygen vacancies are easily formed in the layer. Therefore, it is preferable to block hydrogen released from the insulating layer 120 by the metal oxide layer 130 in order to suppress reduction of the oxide semiconductor layer 140.

In addition, after the oxide semiconductor layer 140 is formed, more oxygen deficiencies are formed on the upper layer side of the oxide semiconductor layer 140 than on the lower layer side in various manufacturing processes (patterning process or etching process). That is, the oxygen deficiencies in the oxide semiconductor layer 140 are non-uniformly distributed in a thickness direction. In this case, if a sufficient amount of oxygen is supplied to repair oxygen vacancies formed on the upper layer side of the oxide semiconductor layer 140, excessive oxygen is supplied to the lower layer side of the oxide semiconductor layer 140. As a result, the excessively supplied oxygen forms a defect level different from the oxygen vacancies, which may lead to a phenomenon such as characteristic fluctuation in a reliability test or a decrease in field-effect mobility. Therefore, blocking the oxygen released from the insulating layer 120 by the metal oxide layer 130 is also preferable in order to suppress excessive oxygen supply to the lower layer side of the oxide semiconductor layer 140.

For example, a thickness of the oxide semiconductor layer 140 is 10 nm or more and 100 nm or less, 15 nm or more and 70 nm or less, or 15 nm or more and 40 nm or less. The oxide semiconductor layer 140 before the heat treatment (OS annealing) described later is amorphous.

When the oxide semiconductor layer 140 is crystallized by OS annealing described later, the oxide semiconductor layer 140 from the formation by a sputtering method to before performing OS annealing is preferably amorphous (a state in which the oxide semiconductor has few crystalline components). That is, it is preferable that the conditions for forming the oxide semiconductor layer 140 are conditions under which the oxide semiconductor layer 140 immediately after formation does not crystallize as much as possible. For example, in the case where the oxide semiconductor layer 140 is formed by a sputtering method, it is desirable to form the oxide semiconductor layer 140 while controlling the temperature of an object to be formed (including the substrate 100 and the structure formed thereon). In addition, the object to be temperature controlled is the object to be formed, but the structure formed on the substrate 100 is very thin, so that it may be considered that the temperature of the substrate 100 is substantially controlled. Therefore, in the following explanation, the object to be formed may be simply referred to as “substrate”.

When a substrate is subjected to thin film formation (deposition) by a sputtering method, ions generated in the plasma and atoms recoiled by a sputtering target collide with the object to be formed (specifically, the structure formed on the substrate 100), so that the temperature of the substrate increases in the process of forming the thin film. When the temperature of the substrate increases in the process of forming the thin film, the oxide semiconductor layer 140 contains microcrystals in a state immediately after the formation, and crystallization due to subsequent OS annealing is inhibited.

In order to control the temperature (that is, the deposition temperature) of the substrate when forming the oxide semiconductor layer 140, for example, a thin film may be formed while cooling the substrate. For example, the substrate can be cooled from the other side of the surface to be film formed so that the deposition temperature may be 100° C. or lower, 70° C. or lower, 50° C. or lower, or 30° C. or lower. In particular, the deposition temperature of the oxide semiconductor layer 140 of the present embodiment is preferably 50° C. or lower. In the present embodiment, the oxide semiconductor layer 140 is formed at a deposition temperature of 50° C. or lower, and OS annealing, which will be described later, is performed at a heat temperature of 400° C. or higher. As described above, in the present embodiment, it is preferable that the difference between the temperature at the time of forming the oxide semiconductor layer 140 and the temperature at the time of performing OS annealing on the oxide semiconductor layer 140 is 350° C. or higher. Forming the oxide semiconductor layer 140 while cooling the substrate makes it possible to obtain the oxide semiconductor layer 140 with few crystalline components in a state immediately after formation.

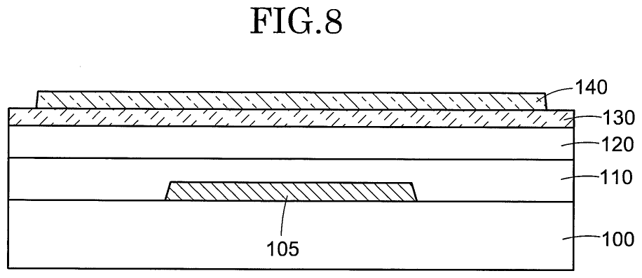

Next, as shown in FIG. 5 and FIG. 8, a pattern (OS pattern) composed of the oxide semiconductor layer 140 is formed (step S1003 of FIG. 5). Although not shown, a resist mask is formed on the oxide semiconductor layer 140, and the oxide semiconductor layer 140 is etched using the resist mask patterned by photolithography. Etching of the oxide semiconductor layer 140 may be performed by wet etching or dry etching. For example, an acidic etchant can be used in the wet etching. Specifically, oxalic acid or hydrofluoric acid can be used as the etchant.

After the oxide semiconductor layer 140 is patterned, heat treatment (OS annealing) is performed on the oxide semiconductor layer 140 (step S1004 of FIG. 5). In the OS annealing, the oxide semiconductor layer 140 in an amorphous state is crystallized by performing a heat treatment on the oxide semiconductor layer 140 at a temperature of 250° C. or higher and 500° C. or lower (preferably 300° C. or higher and 500° C. or lower, and more preferably 350° C. or higher and 450° C. or lower) in an atmospheric atmosphere. The heating atmosphere is not limited to the atmospheric atmosphere, but is preferably an oxidizing atmosphere (an atmosphere containing oxygen). In addition, the oxidizing atmosphere is more preferably a wet atmosphere (specifically, a wet atmospheric atmosphere). In addition, the treatment time of the heat treatment is 15 minutes or more and 120 minutes or less, or 30 minutes or more and 60 minutes or less after reaching a predetermined temperature. In the present embodiment, a temperature of the OS annealing is set to 350° C.

In the present embodiment, a substrate on which the patterned oxide semiconductor layer 140 is formed is charged into a heating furnace having a heating medium (for example, a support plate) maintained at a set temperature (250° C. or higher and 500° C. or lower, in the present embodiment, 350° C.) in advance. The support plate as a heating medium serves to support the substrate and to heat the substrate and the coating formed on the substrate (including the oxide semiconductor layer 140). When a substrate on which the oxide semiconductor layer 140 is formed on the support plate is placed, the oxide semiconductor layer 140 is rapidly heated. When installing the substrate in the heating furnace, it is desirable to keep the temperature drop of the support plate within 15%, within 10%, or within 5% of the set temperature. That is, it is preferable to control the temperature of the support plate so that the oxide semiconductor layer 140 reaches the set temperature in as short a time as possible.

In addition, although an example in which the OS annealing is performed after forming the OS pattern is shown in the present embodiment, the present invention is not limited to this example, and the OS annealing may be performed on the oxide semiconductor layer 140 before forming the OS pattern. In this case, since the crystallized oxide semiconductor layer 140 is etched to form the OS pattern, the etching process is preferably dry-etched.

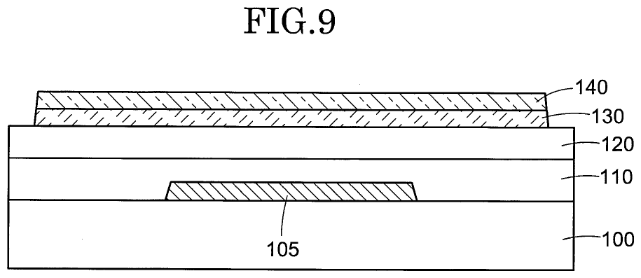

Next, as shown in FIG. 5 and FIG. 9, a pattern (AlOₓ pattern) composed of the metal oxide layer 130 is formed (step S1005 in FIG. 5). The crystallized oxide semiconductor layer 140 has etching resistance to hydrofluoric acid. Therefore, the metal oxide layer 130 of the present embodiment is etched using the oxide semiconductor layer 140 patterned in the above-described process as a mask. Etching of the metal oxide layer 130 may be performed by wet etching or dry etching. For example, dilute hydrofluoric acid (DHF) is used in the wet etching. The photolithography process can be omitted by etching the metal oxide layer 130 using the oxide semiconductor layer 140 as a mask. In addition, since the metal oxide layer 130 is etched using the oxide semiconductor layer 140 as a mask, the metal oxide layer 130 and the oxide semiconductor layer 140 have the same pattern shape.

Although an example in which the OS pattern is formed and then an AlOₓ pattern is formed using the OS pattern as a mask is shown in the present embodiment, the OS pattern and the AlOₓ pattern may be collectively formed. In this case, the oxide semiconductor layer 140 and the metal oxide layer 130 may be simultaneously etched using the same resist mask in step S1003 of FIG. 5.

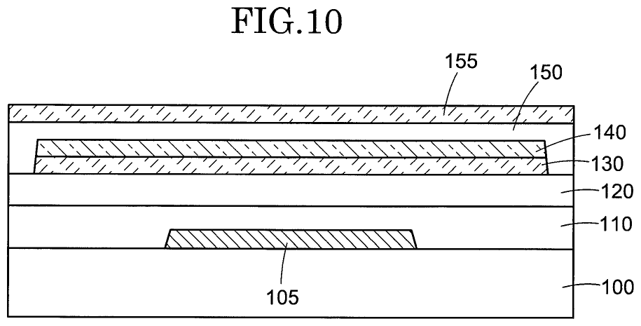

Next, as shown in FIG. 5 and FIG. 10, the gate insulating layer 150 is formed (step S1006 in FIG. 5). For example, a silicon oxide layer is formed as the gate insulating layer 150. The gate insulating layer 150 is formed by the CVD method. It is desirable to form an insulating layer having as few defects as possible. In the present embodiment, the deposition temperature of the gate insulating layer 150 is 350° C. For example, a thickness of the gate insulating layer 150 is 50 nm or more and 300 nm or less, 60 nm or more and 200 nm or less, or 70 nm or more and 150 nm or less. In the present embodiment, the thickness of the gate insulating layer 150 is 100 nm.

Next, in the present embodiment, after the gate insulating layer 150 is formed, a metal oxide layer 155 is formed on the gate insulating layer 150 (step S1007 of FIG. 5). The metal oxide layer 155 is formed by a sputtering method. By using a sputtering method for forming the metal oxide layer 155, oxygen is implanted into the gate insulating layer 150 when forming the metal oxide layer 155. Therefore, the gate insulating layer 150 after the metal oxide layer 155 is formed contains a large amount of oxygen.

For example, a thickness of the metal oxide layer 155 is 5 nm or more and 100 nm or less, 5 nm or more and 50 nm or less, 5 nm or more and 30 nm or less, or 7 nm or more and 15 nm or less. In the present embodiment, aluminum oxide is used as the metal oxide layer 155. As described above, since aluminum oxide has a high barrier property against gas, it is possible to suppress the oxygen implanted into the gate insulating layer 150 from diffusing upward during the heat treatment described later.

In the case where the metal oxide layer 155 is formed by a sputtering method, a process gas used in sputtering remains in the film of the metal oxide layer 155. For example, in the case where Ar is used as the process gas for sputtering, Ar may remain in the film of the metal oxide layer 155. The remaining Ar can be detected by SIMS (Secondary lon Mass Spectrometry) spectrometry or the like with respect to the metal oxide layer 155.

Next, a heat treatment (oxidation annealing) for supplying oxygen to the oxide semiconductor layer 140 is performed in a state where the metal oxide layer 155 is formed on the gate insulating layer 150 (step S1008 of FIG. 5). In other words, a heat treatment (oxidation annealing) is performed on the patterned metal oxide layer 130 and the oxide semiconductor layer 140. During the process from the formation of the oxide semiconductor layer 140 to the formation of the gate insulating layer 150 on the oxide semiconductor layer 140, oxygen vacancies may occur on the upper surface and the side surface of the oxide semiconductor layer 140. Oxidation annealing supplies oxygen released from the insulating layer 120 and the gate insulating layer 150 to the oxide semiconductor layer 140 and repairs the oxygen vacancies. The oxidation annealing may be performed at a temperature of 250° C. or higher and 500° C. or lower (preferably 300° C. or higher and 500° C. or lower, and more preferably 350° C. or higher and 450° C. or lower). In the present embodiment, the oxidation annealing is performed at a temperature of 350° C.

Since the oxygen released from the insulating layer 120 by the oxidation annealing is blocked by the metal oxide layer 130, oxygen is not easily supplied to the lower surface of the oxide semiconductor layer 140. Oxygen released from the insulating layer 120 diffuses from the region where the metal oxide layer 130 is not formed to the gate insulating layer 150 and reaches the oxide semiconductor layer 140 via the gate insulating layer 150. As a result, the oxygen released from the insulating layer 120 is less likely to be supplied to the lower surface of the oxide semiconductor layer 140, and is mainly supplied to the side surface and the upper surface of the oxide semiconductor layer 140. Further, the oxygen released from the gate insulating layer 150 is supplied to the upper surface and the side surface of the oxide semiconductor layer 140 by the oxidation annealing. Hydrogen may be released from the insulating layer 110 by the above oxidation annealing. However, the hydrogen may be trapped in the oxygen contained in the insulating layer 120 or blocked by the metal oxide layer 130 before reaching the oxide semiconductor layer 140.

As described above, the oxidation annealing makes it possible to supply oxygen to the upper surface and the side surface of the oxide semiconductor layer 140 having a relatively large amount of oxygen vacancies while suppressing the supply of oxygen to the lower surface of the oxide semiconductor layer 140 having a small amount of oxygen vacancies. Similarly, during the oxidation annealing, since the upward diffusion of the oxygen implanted into the gate insulating layer 150 is blocked by the metal oxide layer 155, the oxygen is prevented from being released into the atmosphere. Therefore, oxygen can be efficiently supplied to the oxide semiconductor layer 140 during the oxidation annealing.

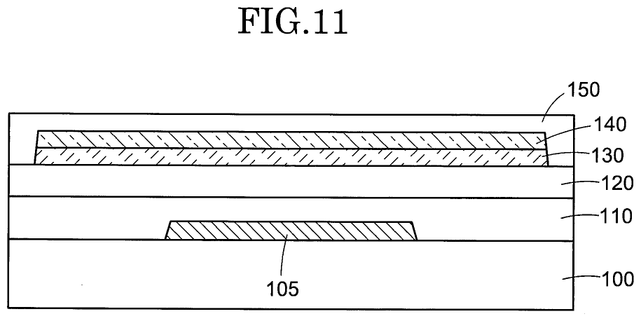

Next, as shown in FIG. 5 and FIG. 11, after the oxidation annealing, the metal oxide layer 155 is etched and removed (step S1009 in FIG. 5). The etching of the metal oxide layer 155 may be wet etching or dry etching. For example, dilute hydrofluoric acid (DHF) is used in the wet etching. The entire metal oxide layer 155 is removed by the etching process of step S1009.

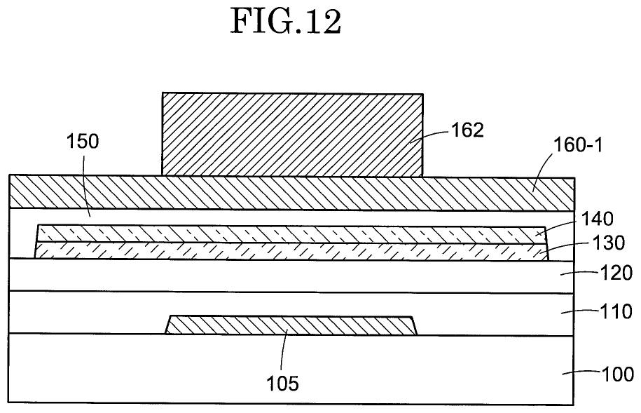

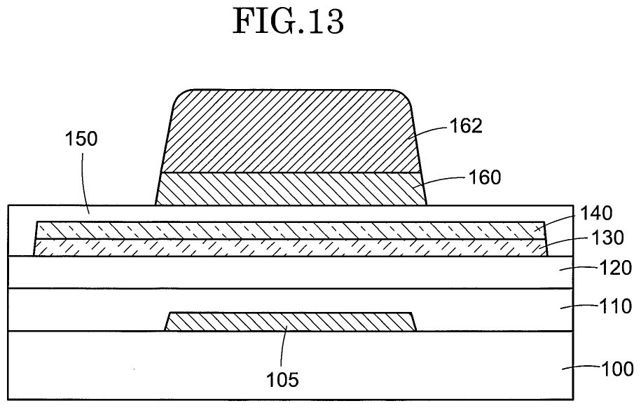

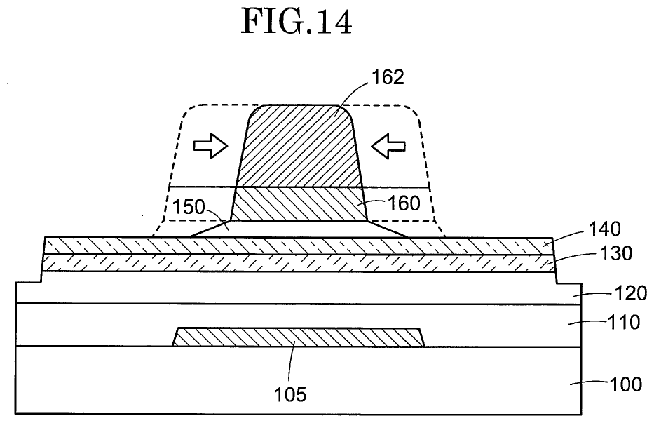

Next, as shown in FIG. 5, FIG. 12, FIG. 13, and FIG. 14, the gate insulating layer 150 is etched after the gate wiring 160 is formed on the gate insulating layer 150 (step S1010 in FIG. 5). First, as shown in FIG. 12, a resist layer 162 is formed by photolithography on a metal layer 160-1 formed by a sputtering method or an atomic layer deposition method.

Next, as shown in FIG. 13, the gate wiring 160 is formed by dry etching the metal layer 160-1 using the resist layer 162 as a mask.

Next, as shown in FIG. 14, after forming the gate wiring 160, the gate insulating layer 150 is etched by further continuing dry etching. That is, the end portion of the gate insulating layer 150 is etched using the resist layer 162 used to form the gate wiring 160. As described above, in the present embodiment, the patterned gate insulating layer 150 and gate wiring 160 are formed by collectively etching the metal layer and the gate insulating layer 150.

In the present embodiment, the gate insulating layer 150 is etched using the resist layer 162 as a mask to expose part of the oxide semiconductor layer 140 (the region functioning as the conductive region 140c). In this case, while the gate insulating layer 150 is etched until part of the oxide semiconductor layer 140 is exposed, the resist layer 162 gradually retreats inward and becomes narrower (see arrows in FIG. 14). Therefore, the end portion of the gate insulating layer 150 is processed into a tapered shape. As a result, the overlapping region 150a overlapping the gate wiring 160 and the non-overlapping region 150b not overlapping the gate wiring 160 are formed in the gate insulating layer 150. In the present embodiment, controlling the etching time of the gate insulating layer 150 makes it possible to set the length of the non-overlapping region 150b in the first direction to a range of 0.3 μm or more and 1.0 μm or less, or set the inclination angle (θ) of the upper surface of the non-overlapping region 150b to 5° or more and 20° or less.

In addition, as shown in FIG. 14, when the gate insulating layer 150 is etched until the oxide semiconductor layer 140 is exposed, the gate insulating layer 150 formed on the insulating layer 120 also disappears, thereby exposing the upper surface of the insulating layer 120. Therefore, if the etching process is continued even after the oxide semiconductor layer 140 is exposed, the upper surface of the insulating layer 120 is abraded, and the step 121 is formed in the vicinity of the end portion of the metal oxide layer 130. Although the case where the step 121 is formed is exemplified in the example shown in FIG. 14, if the etching process is stopped when the oxide semiconductor layer 140 is exposed, the step 121 is not substantially formed. However, it is desirable to continue the etching sufficiently until part of the oxide semiconductor layer 140 is completely exposed because if the gate insulating layer 150 remains on the oxide semiconductor layer 140 (specifically, the region used as the conductive region 140c), it may lead to contact failure or shifting of the threshold voltage. In the present embodiment, the etching time required for the upper surface of the oxide semiconductor layer 140 to be exposed is slightly over-etched (for example, the etching time described above is extended by 10%).

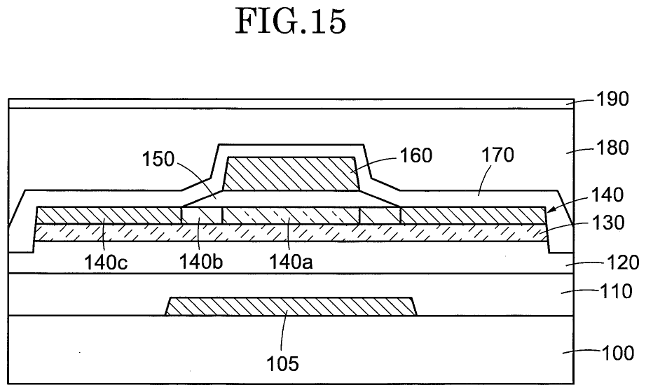

Next, as shown in FIG. 5 and FIG. 15, the insulating layers 170 to 190 are formed as the passivation layer on the gate insulating layer 150 and the gate wiring 160 (step S1011 of FIG. 5). The insulating layers 170 to 190 are formed by the CVD method. In the present embodiment, a silicon oxide layer is formed as the insulating layer 170, and a silicon nitride layer is formed as the insulating layer 180. In addition, a silicon oxide layer is formed as the insulating layer 190. The deposition temperature of the insulating layers 170 to 190 is preferably set to 250° C. or higher and 500° C. or lower (preferably 300° C. or higher and 450° C. or lower, and more preferably 325° C. or higher and 400° C. or lower). In the present embodiment, the deposition temperature of the insulating layers 170 to 190 is set to 350° C. In addition, the thicknesses of the insulating layers 170 to 190 may be 30 nm or more and 500 nm or less. In the present embodiment, the thickness of the insulating layer 170 is 100 nm, and the thickness of the insulating layer 180 is 300 nm. In addition, the thickness of the insulating layer 190 is 30 nm.

The insulating layers 170 to 190 function as the passivation layer (protective layer) to prevent gas and moisture from entering from the outside. In addition, the insulating layers 170 to 190 also serve to insulate the gate wiring 160 and the source/drain wiring 200, as described above. Further, in the present embodiment, the insulating layers 170 to 190 (in particular, the insulating layer 180) are formed to form the conductive region 140c in the oxide semiconductor layer 140.

The insulating layer 180 of the present embodiment is composed of a silicon nitride layer. Since ammonia is used as the source gas when forming the insulating layer 180 by the CVD method, the insulating layer 180 contains a large amount of hydrogen. Therefore, when the insulating layer 180 is formed and after the insulating layer 180 is formed, the insulating layer 180 is heated to diffuse hydrogen from the insulating layer 180. The diffused hydrogen reaches the oxide semiconductor layer 140 via the insulating layer 170. In this case, oxygen contained in the region of the oxide semiconductor layer 140 in contact with the insulating layer 170 is reduced, and oxygen vacancies are formed. Hydrogen is trapped in the oxygen vacancies formed to form a donor level. As a result, the resistance of part of the oxide semiconductor layer 140 to which hydrogen is supplied is reduced and becomes the conductive region 140c.

On the other hand, since hydrogen does not reach the oxide semiconductor layer 140 positioned directly below the gate wiring 160, the resistance is not reduced and becomes the channel region 140a. In addition, since hydrogen diffuses in a region between the channel region 140a and the conductive region 140c at a lower concentration than that of the conductive layer 140c, it becomes the LDD region 140b having a higher resistance than the conductive region 140c.

The reason for the suppression of the diffusion of hydrogen is that a large number of defects is formed on the upper surface of the insulating layer 120 functioning as a base layer by etching the gate insulating layer 150. In a plan view, the insulating layer 120 and the insulating layer 170 are in direct contact with each other around the oxide semiconductor layer 140. Therefore, most of the hydrogen diffused from the insulating layer 180 is trapped on the upper surface of the insulating layer 120, and the amount of hydrogen diffused toward the oxide semiconductor layer 140 is suppressed. In this case, since the conductive region 140c of the oxide semiconductor layer 140 is in direct contact with the insulating layer 170, the resistance is sufficiently reduced even if the amount of hydrogen to be diffused is small, but the amount of hydrogen to be diffused downward of the gate wiring 160 is extremely small. Moreover, in the present embodiment, the diffusion of hydrogen through the gate insulating layer 150 is also suppressed because defects that suppress the diffusion of hydrogen are also formed on the upper surface of the non-overlapping region 150b of the gate insulating layer 150.

In addition, the reason why the diffusion of hydrogen is suppressed is that a large amount of oxygen is contained in the insulating layer 120 functioning as the base layer. Oxygen contained in the insulating layer 120 serves to capture hydrogen. For example, in order to increase the oxygen content of the insulating layer 120, it is preferable to set the deposition temperature of the insulating layer 120 to be relatively low. In the present embodiment, it is set to 350° C., but may be within a range of 250° C. or higher to 500° C. or less (preferably 300° C. or higher to 450° C. or less, more preferably 325° C. or higher to 400° C. or less).

In addition, although a process of forming the metal oxide layer 130 on the insulating layer 120 is included in the present embodiment, this process also contributes to increasing the oxygen content of the insulating layer 120. Specifically, when the metal oxide layer 130 is formed by sputtering, oxygen is implanted into the insulating layer 120. As a result, the total amount of oxygen in the insulating layer 120 can be increased because oxygen is further implanted into the insulating layer 120 in which the oxygen content is increased at the above-described deposition temperature.

As described above, the semiconductor device 10 of the present embodiment has the non-overlapping region 150b not overlapping the gate wiring 160 at the end portion of the gate insulating layer 150. The non-overlapping region 150b of the gate insulating layer 150 suppresses the diffusion of hydrogen via the gate insulating layer 150. Therefore, the region of the oxide semiconductor layer 140 positioned below the non-overlapping region 150b has a lower hydrogen-concentration (higher resistance) LDD region 140b than the conductive region 140c. As described above, according to the present embodiment, the LDD region 140b and the conductive region 140c can be simultaneously formed by reducing the resistance of part of the oxide semiconductor layer 140 using the hydrogen diffused from the insulating layer 180.

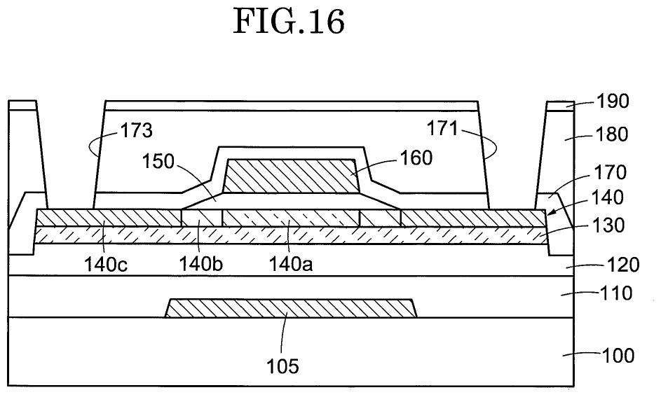

Next, as shown in FIG. 5 and FIG. 16, the openings 171 and 173 are formed in the insulating layers 170 to 190 (step S1012 of FIG. 5). The openings 171 and 173 expose part of the conductive region 140c.

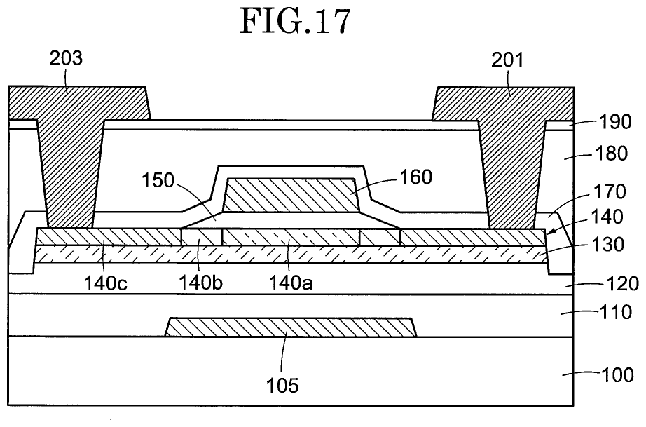

Finally, as shown in FIG. 5 and FIG. 17, the source/drain wiring 200 is formed on the conductive region 140c exposed by the openings 171 and 173 and on the insulating layer 180 (step S1013 of FIG. 5). The semiconductor device 10 shown in FIG. 1 is completed by the above-described process.

In the semiconductor device 10 prepared by the manufacturing method of the present embodiment, electrical characteristics having a field-effect mobility of 20 cm²/Vs or more, 25 cm²/Vs or more, or 30 cm²/Vs or more can be obtained in a range where the channel length L of the channel region 140a is 1 μm or more and 4 μm or less and the channel width of the channel region 140a is 2 μm or more and 25 μm or less. The “field-effect mobility” in the present embodiment means the field-effect mobility in a saturated region of the semiconductor device 10, which means the maximum value of the field-effect mobility in a region where a potential difference (Vd) between the source wiring 201 and the drain wiring 203 is greater than a value (Vg-Vth) obtained by subtracting a threshold voltage (Vth) of the semiconductor device 10 from a voltage (Vg) supplied to the gate wiring 160.

### [Modifications]

Although an example in which the non-overlapping region 150b of the gate insulating layer 150 is a tapered shape in a cross-sectional view is shown in FIG. 1, the present invention is not limited to this example. For example, the non-overlapping region 150b may be a rectangular region leaving the thickness of the gate insulating layer 150 as it is. In this case, for example, when the gate insulating layer 150 is etched, a resist mask for forming the non-overlapping region 150b may be arranged, and the gate insulating layer 150 from the end portion of the gate wiring 160 to a predetermined range may be intentionally left.

### Second Embodiment

Although the semiconductor device 10 of the first embodiment has the metal oxide layer 130 below the oxide semiconductor layer 140, the present invention is not limited to this example, and the metal oxide layer 130 may be omitted.

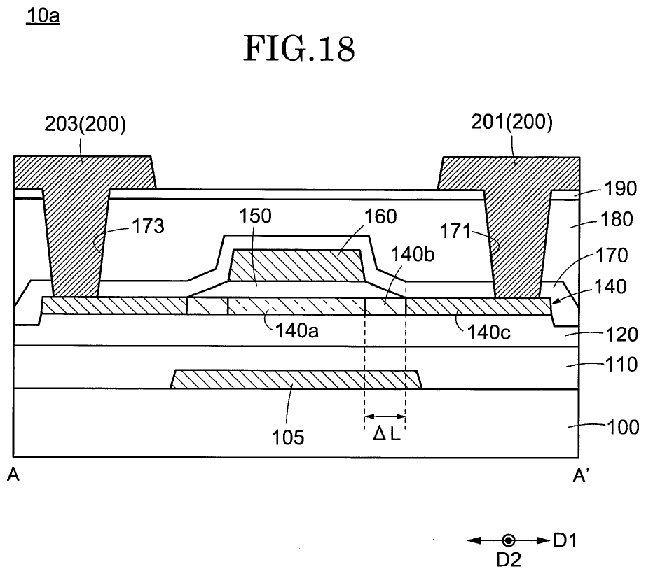

FIG. 18 is a schematic cross-sectional view showing a configuration of a semiconductor device 10a according to an embodiment of the present invention. As shown in FIG. 18, the oxide semiconductor layer 140 is arranged on the insulating layer 120 and is in contact with the insulating layer 120. Even in such a configuration, in the process of forming the conductive region 140c described in the first embodiment, defects arranged on the upper surface of the insulating layer 120 and the upper surface of the gate insulating layer 150 on the non-overlapping region 150b suppress the diffusion of hydrogen into the channel region 140a.

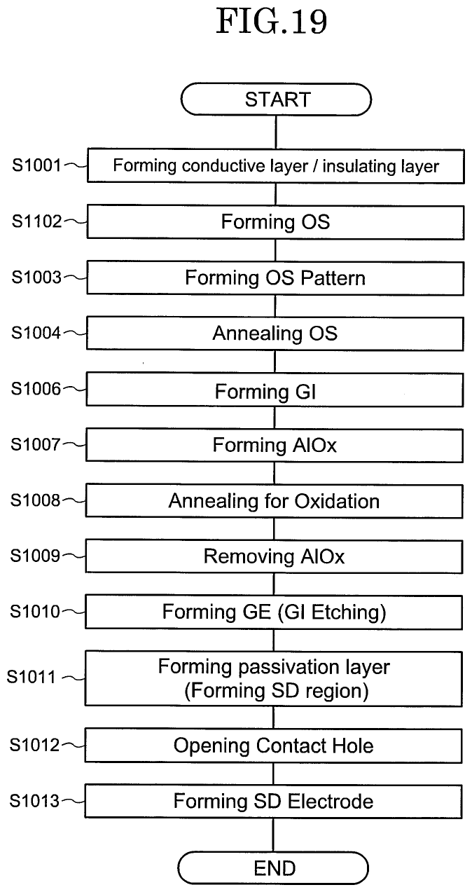

FIG. 19 is a sequence diagram showing a method for manufacturing the semiconductor device 10a according to an embodiment of the present invention. In the manufacturing process of the semiconductor device 10a of the present embodiment, the process related to the metal oxide layer 130 is omitted from the sequence diagram shown in FIG. 5 in the first embodiment. Specifically, as shown in FIG. 19, step S1002 (Forming OS/AlOₓ) of FIG. 5 is changed to step S1102 (Forming OS), and step S1005 of FIG. 5 is omitted. The other processes are the same as the sequence diagram shown in FIG. 5.

In addition, the semiconductor device 10a of the present embodiment may be manufactured by omitting steps S1007 to S1009 from the sequence diagram shown in FIG. 19.

### Third Embodiment

A semiconductor device manufactured in a method different from that of the first embodiment will be described in the present embodiment. The semiconductor device of the present embodiment has the same configuration as the semiconductor device 10 described in the first embodiment.

Therefore, in the following explanation, the semiconductor device of the present embodiment will be referred to as “the semiconductor device 10”. The present embodiment will be described focusing on differences from the first embodiment.

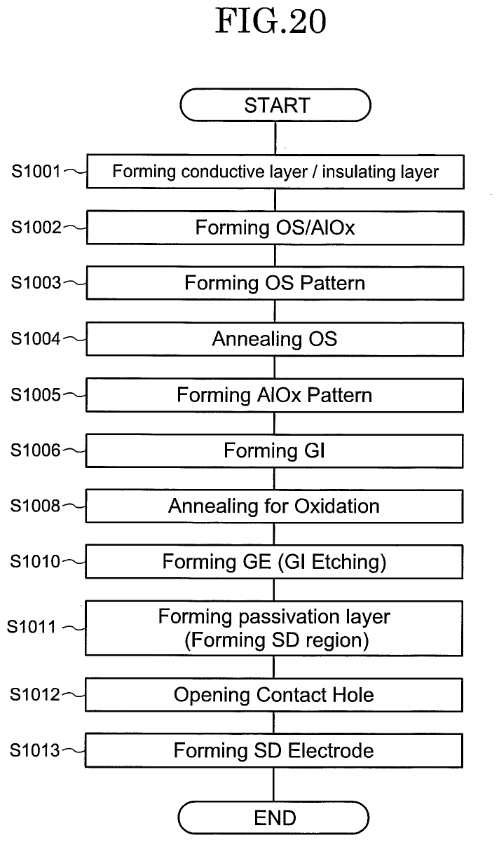

FIG. 20 is a sequence diagram showing a method for manufacturing the semiconductor device 10 according to an embodiment of the present invention. As shown in FIG. 20, two steps of step S1007 (Forming AlOₓ) and step S1009 (Removing AlOₓ) shown in FIG. 5 are omitted in the present embodiment. That is, in the present embodiment, after the gate insulating layer 150 is formed, oxidation annealing is performed in that state. Oxygen released from the gate insulating layer 150 is supplied to the oxide semiconductor layer 140 by the oxidation annealing, and the oxygen vacancies contained in the oxide semiconductor layer 140 are repaired. Since the role of the metal oxide layer 130 in this case is the same as that of the first embodiment, descriptions thereof will be omitted.

### Fourth Embodiment

A semiconductor device manufactured in a method different from that of the first embodiment will be described in the present embodiment. Specifically, in the present embodiment, the metal oxide layer 130 is used as an etching stopper when the etching process of the gate insulating layer 150 is performed. The present embodiment will be described focusing on differences from the first embodiment.

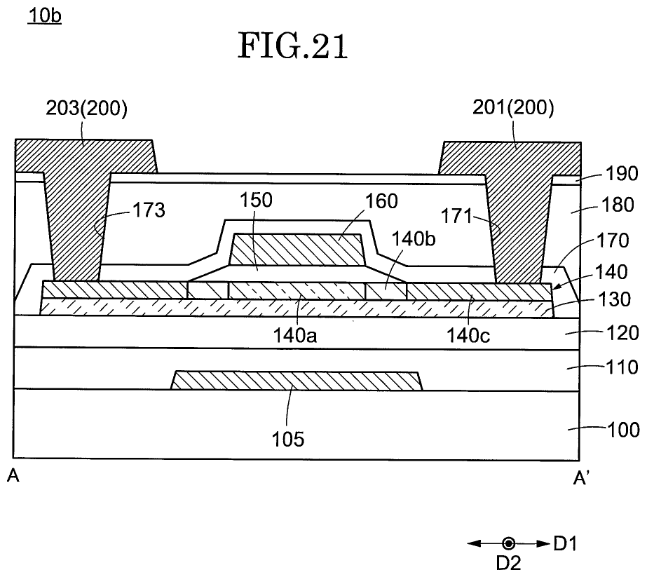

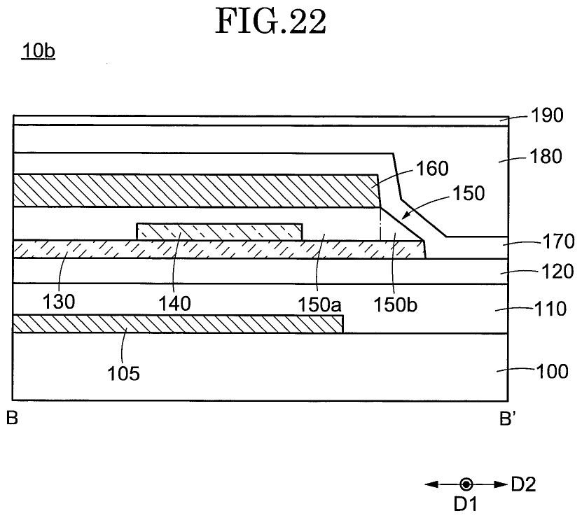

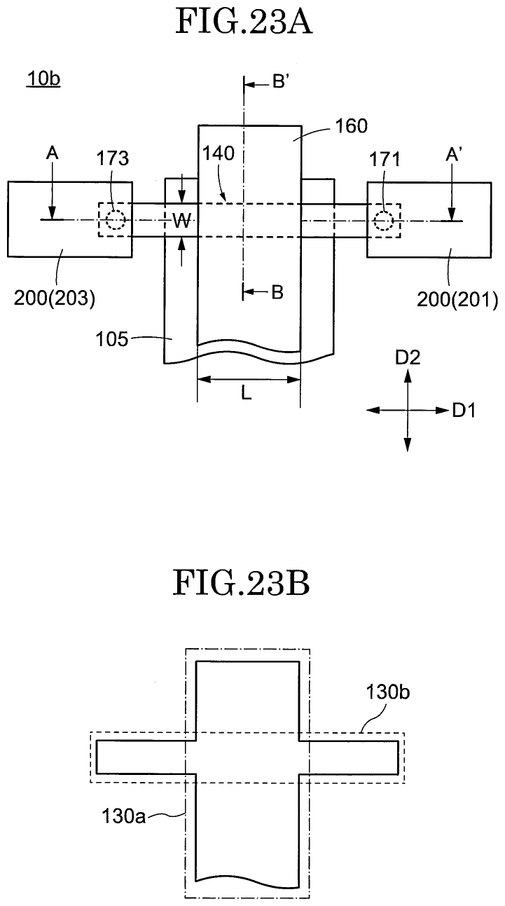

FIG. 21 and FIG. 22 are schematic cross-sectional views showing a configuration of a semiconductor device 10b according to an embodiment of the present invention. FIG. 23A is a schematic plan view showing a configuration of the semiconductor device 10b according to an embodiment of the present invention. FIG. 23B is a schematic plan view showing the configuration of the metal oxide layer 130 in the semiconductor device 10b according to an embodiment of the present invention. In addition, FIG. 21 corresponds to a cross-sectional view cut along a dashed-dotted line indicated by A-A′ shown in FIG. 23A. FIG. 22 corresponds to a cross-sectional view cut along a dashed-dotted line indicated by B-B′ shown in FIG. 23A.

As shown in FIG. 21, the semiconductor device 10b of the present embodiment is different from the semiconductor device 10 of the first embodiment in that the insulating layer 120 does not have the step 121 (see FIG. 1). In the present embodiment, when the etching process of the gate insulating layer 150 is performed, the upper surface of the insulating layer 120 is covered with the metal oxide layer 130. Therefore, the upper surface of the insulating layer 120 is not etched as in the first embodiment even if the gate insulating layer 150 on the insulating layer 120 is removed. Since the other configurations are the same as the semiconductor device 10 of the first embodiment shown in FIG. 1, detailed descriptions thereof will be omitted.

The cross-sectional view along the first direction is similar to that of the first embodiment, but the cross-sectional view along the second direction shown in FIG. 22 is different from the semiconductor device 10 of the first embodiment. For example, although not shown, in the semiconductor device 10 of the first embodiment, end portions of the metal oxide layer 130 and the oxide semiconductor layer 140 coincide with each other in the second direction (direction D2), whereas in the semiconductor device 10b of the present embodiment, the end portions of the metal oxide layer 130 and the oxide semiconductor layer 140 do not coincide with each other in the second direction, as shown in FIG. 22.

In addition, the metal oxide layer 130 overlaps the gate insulating layer 150 and the gate wiring 160. As shown in FIG. 22, the non-overlapping region 150b is formed at the end portion of the gate insulating layer 150 in the second direction. Therefore, although the entire metal oxide layer 130 overlaps the gate insulating layer 150, part of the region overlaps the gate wiring 160. That is, in the semiconductor device 10b, the end portion of the metal oxide layer 130 approximately coincides with the end portion of the gate insulating layer 150 in the second direction and does not coincide with the end portion of the gate wiring 160.

As will be described later, the method for manufacturing the semiconductor device 10b of the present embodiment includes a process of etching the metal oxide layer 130 using the gate wiring 160, the gate insulating layer 150 (specifically, the non-overlapping region 150b of the gate insulating layer 150), and the oxide semiconductor layer 140 as masks. Therefore, the metal oxide layer 130 is patterned in a self-aligned manner using the gate wiring 160, the gate insulating layer 150, and the oxide semiconductor layer 140 as masks. As a result, the metal oxide layer 130 has the same pattern shape as the union of the pattern shape of the gate insulating layer 150 and the pattern shape of the oxide semiconductor layer 140. In addition, as shown in FIG. 23B, the union of the pattern shape of the gate insulating layer 150 and the pattern shape of the oxide semiconductor layer 140 refers to a pattern shape obtained by integrating a pattern 130a derived from the pattern shape of the gate insulating layer 150 and a pattern 130b derived from the pattern shape of the oxide semiconductor layer 140.

As is apparent from FIG. 21, FIG. 22, FIG. 23A, and FIG. 23B, the metal oxide layer 130 has a first region overlapping the gate wiring 160 and the oxide semiconductor layer 140, a second region overlapping the oxide semiconductor layer 140 and not overlapping the gate wiring 160, and a third region overlapping the gate wiring 160 and the gate insulating layer 150 and not overlapping the oxide semiconductor layer 140. Specifically, in FIG. 21 and FIG. 23A, the first region corresponds to a region in contact with the channel region 140a. In FIG. 21 and FIG. 23A, the second region corresponds to a region in contact with the LDD region 140b and the conductive region 140c.

As is clear from FIG. 22, in the semiconductor device 10b of the present embodiment, the non-overlapping region 150b is also formed on the end portion of the gate insulating layer 150 in the second direction. Therefore, the semiconductor device 10b can suppress the diffusion of hydrogen toward the oxide semiconductor layer 140 along the second direction. Other advantages of the semiconductor device 10b are the same as those of the first embodiment.

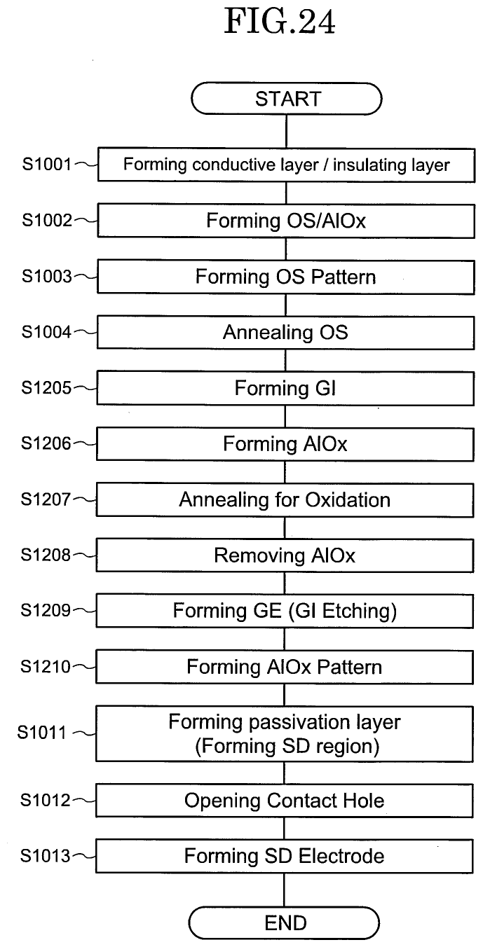

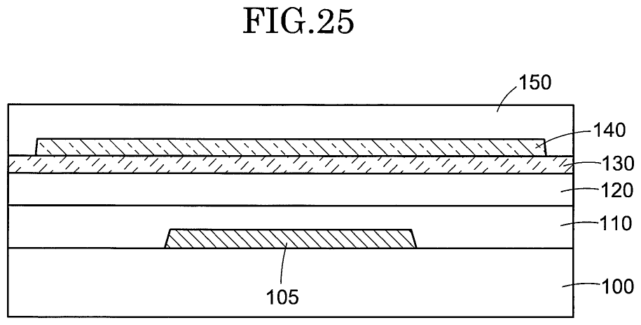

FIG. 24 is a sequence diagram showing a method for manufacturing the semiconductor device 10b according to an embodiment of the present invention. FIG. 25 to FIG. 28 are schematic cross-sectional views showing the method for manufacturing the semiconductor device 10b according to an embodiment of the present invention.

First, as shown in FIG. 24, steps S1001 to S1004 are performed by the same process as in the first embodiment, and a heat treatment (OS annealing) of the oxide semiconductor layer 140 is completed. When the heat treatment of the oxide semiconductor layer 140 is completed, steps S1205 to S1208 are performed without etching the metal oxide layer 130, and the oxidation annealing is completed. Steps S1205 to S1208 of FIG. 24 are the same as the process of steps S1006 to S1009 of FIG. 5 described in the first embodiment.

FIG. 25 shows a cross-sectional view of a state in which the process up to this point is completed. As shown in FIG. 25, in the present embodiment, the metal oxide layer 130 remains below the gate insulating layer 150 without being etched.

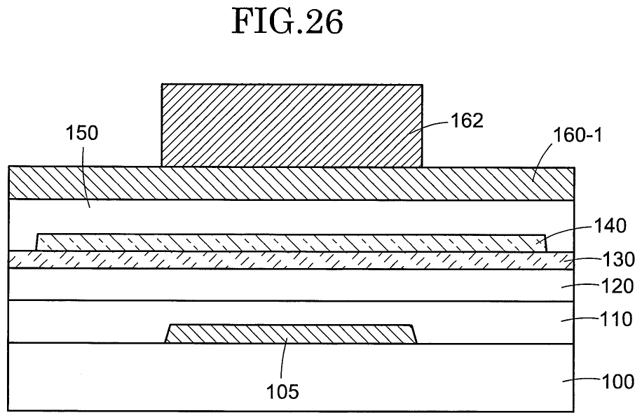

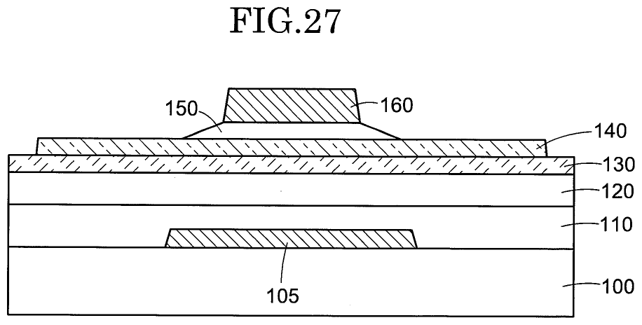

Next, as shown in FIG. 24, FIG. 26, and FIG. 27, the gate insulating layer 150 is etched after the gate wiring 160 is formed on the gate insulating layer 150 (step S1209 of FIG. 24). First, as shown in FIG. 26, the resist layer 162 is formed by photolithography on the metal layer 160-1 formed by a sputtering method or an atomic layer deposition method.

Next, as shown in FIG. 27, the gate wiring 160 is formed by dry etching the metal layer 160-1 using the resist layer 162 as a mask. Further, after the gate wiring 160 is formed, the gate insulating layer 150 is etched by continuing dry etching. The process of etching the metal layer 160-1 and the gate insulating layer 150 is the same as that of the first embodiment.

In this case, in the present embodiment, even if the etching process is continued after part of the oxide semiconductor layer 140 is exposed, since the upper surface of the insulating layer 120 is covered with the metal oxide layer 130, the insulating layer 120 can be prevented from being etched. That is, the metal oxide layer 130 can function as an etching stopper in the etching process of the gate insulating layer 150. Therefore, since the etching time of the gate insulating layer 150 can be sufficiently long without forming the step 121 (see FIG. 1) in the insulating layer 120, a large process margin for exposing part of the oxide semiconductor layer 140 (the region used as the conductive region 140c) can be ensured. In addition, making the etching time of the gate insulating layer 150 sufficiently long makes it possible to form a sufficiently long LDD region 140b.

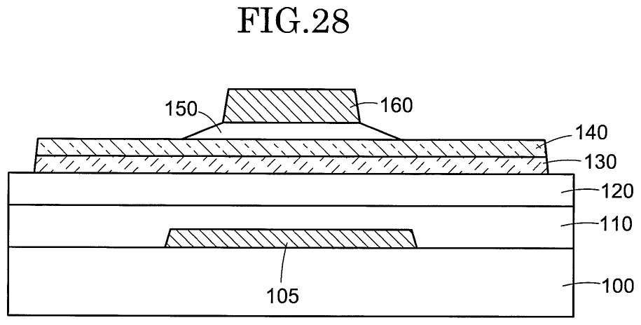

When the etching process of the gate insulating layer 150 is completed, as shown in FIG. 24 and FIG. 28, a pattern (AlOₓ pattern) composed of the metal oxide layer 130 is formed (step S1210 in FIG. 24). The process of etching the metal oxide layer 130 is the same as that of the first embodiment. In addition, the non-overlapping region 150b of the gate insulating layer 150 may also be etched when etching the metal oxide layer 130. However, in the present embodiment, since the thickness of the gate insulating layer 150 (for example, 100 nm) is sufficiently thick with respect to the thickness (3 nm in the present embodiment) of the metal oxide layer 130, etching of the overlapping region 150b can be substantially ignored.

In the semiconductor device 10b of the present embodiment, electrical characteristics having a field-effect mobility of 20 cm²/Vs or more, 25 cm²/Vs or more, or 30 cm²/Vs or more can be obtained in the channel length L of the channel region 140a of 1 μm or more and 4 μm or less and a channel width of the channel region 140a of 2 μm or more and not more than 25 μm. The definition of the field-effect mobility in the present embodiment is the same as that in the first embodiment.

### Fifth Embodiment

A semiconductor device manufactured by a method different from the fourth embodiment will be described in the present embodiment. The semiconductor device of the present embodiment has the same configuration as the semiconductor device 10b described in the fourth embodiment. Therefore, in the following explanation, the semiconductor device of the present embodiment will be referred to as “the semiconductor device 10b”. The present embodiment will be described focusing on differences from the fourth embodiment.

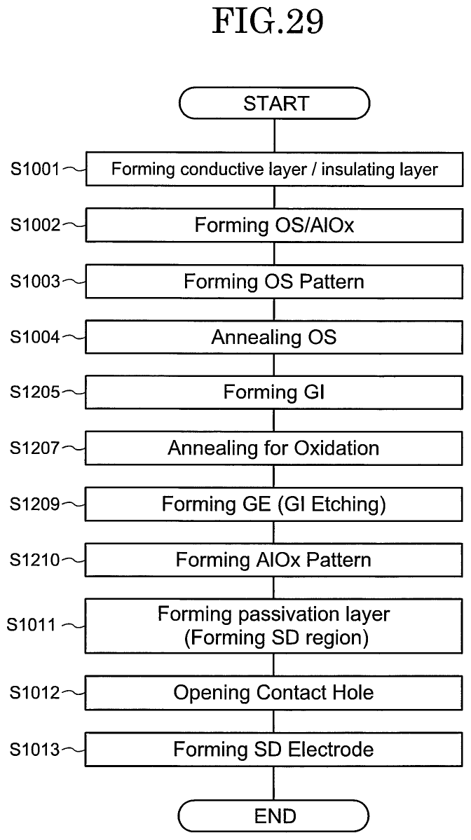

FIG. 29 is a sequence diagram showing a method for manufacturing the semiconductor device 10b according to an embodiment of the present invention. As shown in FIG. 29, two steps of step S1206 (Forming AlOₓ) and step S1208 (Removing AlOₓ) shown in FIG. 24 are omitted in the present embodiment. That is, in the present embodiment, after the gate insulating layer 150 is formed, oxidation annealing is performed in that state. Oxygen released from the gate insulating layer 150 is supplied to the oxide semiconductor layer 140 by the oxidation annealing, and the oxygen vacancies contained in the oxide semiconductor layer 140 are repaired. Since the role of the metal oxide layer 130 in this case is the same as that of the fourth embodiment, descriptions thereof will be omitted.

### Sixth Embodiment

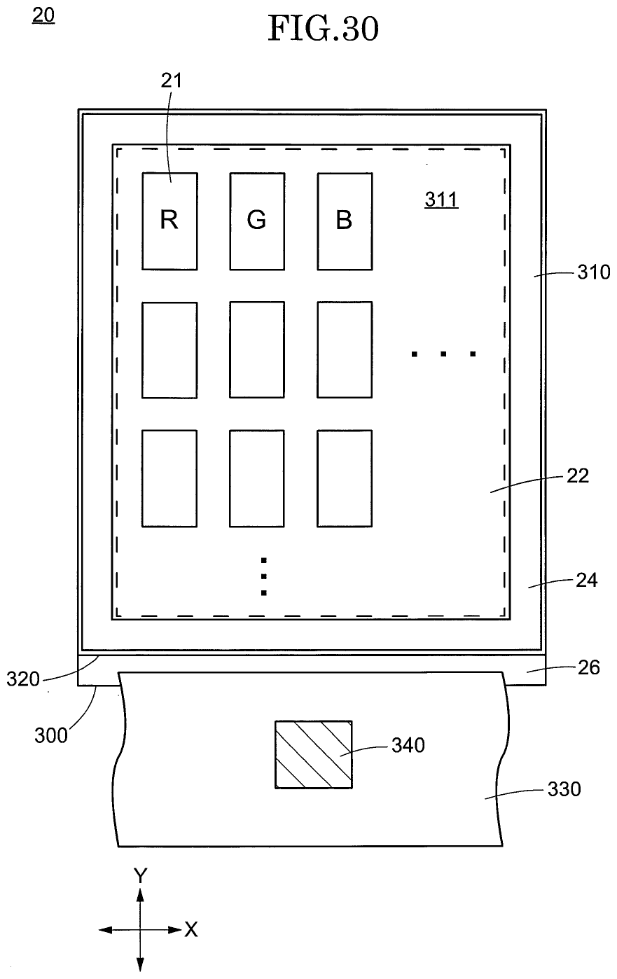

A display device 20 using a semiconductor device according to an embodiment of the present invention will be described with reference to FIG. 30 to FIG. 36. In the embodiment described below, a configuration in which the semiconductor device 10 described in the first embodiment is applied to a circuit of a liquid crystal display device will be described. However, the semiconductor device of any of the second to fourth embodiments may be applied to the circuit of the liquid crystal display device.

### [Outline of Display Device]

FIG. 30 is a schematic plan view showing an entire configuration of the display device 20 according to an embodiment of the present invention. As shown in FIG. 30, the display device 20 includes an array substrate 300, a seal portion 310, a counter substrate 320, a flexible printed circuit (FPC) substrate 330, and an IC chip 340. The array substrate 300 and the counter substrate 320 are bonded together by the seal portion 310. A plurality of pixels 21 is arranged in a matrix in the liquid crystal region 22 surrounded by the seal portion 310. The liquid crystal region 22 is a region overlapping a liquid crystal element 311 described later in a plan view. In addition, for the pixel 21, the letters “R,” “G,” and “B” indicate that they correspond to a pixel for displaying red, a pixel for displaying green, and a pixel for displaying blue, respectively.

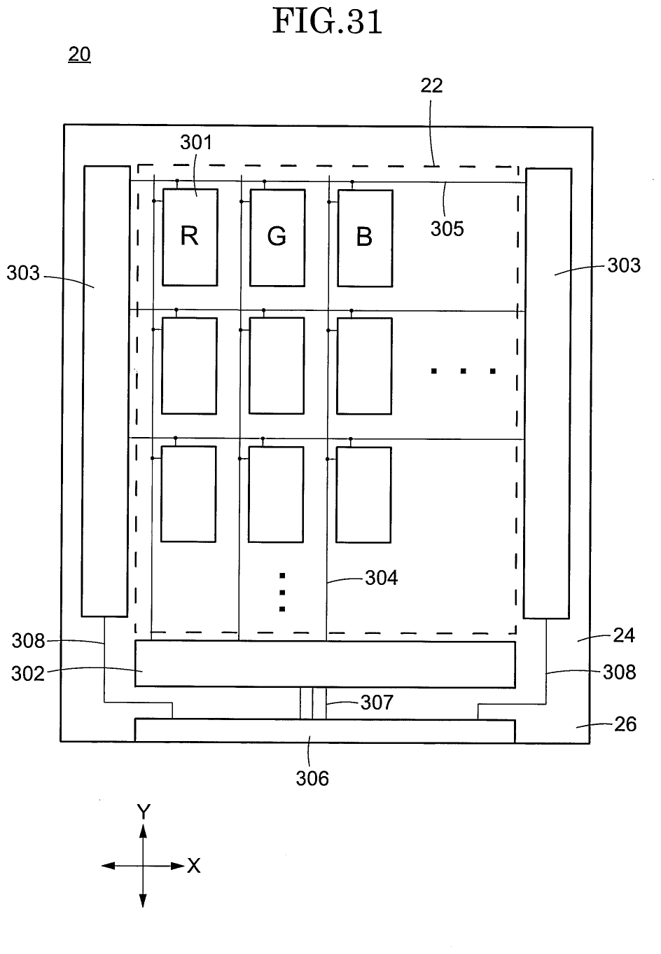

The flexible printed circuit substrate 330 is arranged in a terminal region 26. The terminal region 26 is a region of the array substrate 300 exposed from the counter substrate 320 and is arranged outside the seal region 24. Outside the seal region 24 means the outside of a region where the seal portion 310 is arranged and a region surrounded by the seal portion 310. The IC chip 340 is arranged on the flexible printed circuit substrate 330. The IC chip 340 supplies a signal for driving each pixel circuit 301 (see FIG. 31) arranged in each pixel 21.

### [Circuit Configuration of Display Device]

FIG. 31 is a diagram showing a circuit configuration of the display device 20 according to an embodiment of the present invention. As shown in FIG. 31, a plurality of pixel circuits 301 is arranged in a matrix corresponding to each pixel 21 shown in FIG. 30. A source driver circuit 302 is arranged at a position adjacent to the liquid crystal region 22 on which the pixel circuit 301 is arranged in a direction Y (column direction). In addition, a gate driver circuit 303 is arranged at a position adjacent to the liquid crystal region 22 in a direction X (row direction). The source driver circuit 302 and the gate driver circuit 303 are arranged in the seal region 24. However, the region where the source driver circuit 302 and the gate driver circuit 303 are arranged is not limited to the seal region 24, and may be any region as long as it is outside the region where the pixel circuit 301 is arranged.

A data signal line 304 extends from the source driver circuit 302 in the direction Y and is connected to the plurality of pixel circuits 301 arranged in the direction Y. A scan signal line 305 extends from the gate driver circuit 303 in the direction X and is connected to the plurality of pixel circuits 301 arranged in the direction X.

A terminal portion 306 is arranged in the terminal region 26. The terminal portion 306 and the source driver circuit 302 are connected by a connecting wiring 307. Similarly, the terminal portion 306 and the gate driver circuit 303 are connected by a connecting wiring 308. The flexible printed circuit substrate 330 is connected to the terminal portion 306, so that the external device and the display device 20 are connected via the flexible printed circuit substrate 330. Each pixel circuit 301 arranged in the display device 20 is driven by signals from the external device input via the flexible printed circuit substrate 330.

The semiconductor device 10 described in the first embodiment is used as a transistor included in the pixel circuit 301, the source driver circuit 302, and the gate driver circuit 303.

### [Pixel Circuit of Display Device]

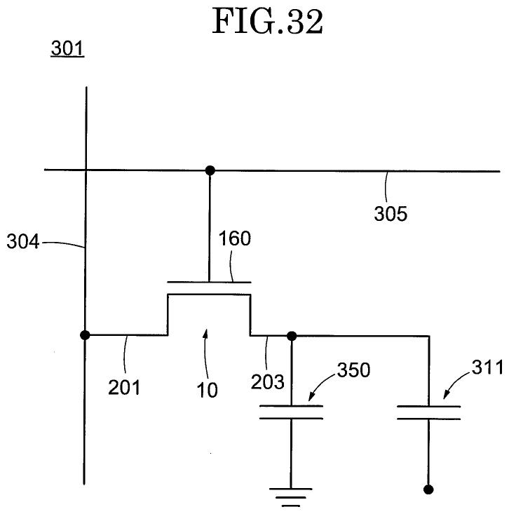

FIG. 32 is a circuit diagram showing a configuration of the pixel circuit 301 of the display device 20 according to an embodiment of the present invention. As shown in FIG. 32, the pixel circuit 301 includes elements such as the semiconductor device 10, a storage capacitor 350, and the liquid crystal element 311.

The semiconductor device 10 includes the gate wiring 160, the source wiring 201, and the drain wiring 203. The gate wiring 160 is connected to the scan signal line 305. However, the gate wiring 160 and the scan signal line 305 may be formed of an integral conductive layer. The source wiring 201 is connected to the data signal line 304. However, the source wiring 201 and the data signal line 304 may be formed of an integral conductive layer.

The drain wiring 203 is connected to the storage capacitor 350 and the liquid crystal element 311. In addition, the roles of the source wiring 201 and the drain wiring 203 may be changed depending on the relationship between the voltage supplied to the data signal line 304 and the voltage stored in the storage capacitor 350. That is, the source wiring 201 may function as a drain wiring and the drain wiring 203 may function as a source wiring.

### [Cross-Sectional Structure of Display Device]

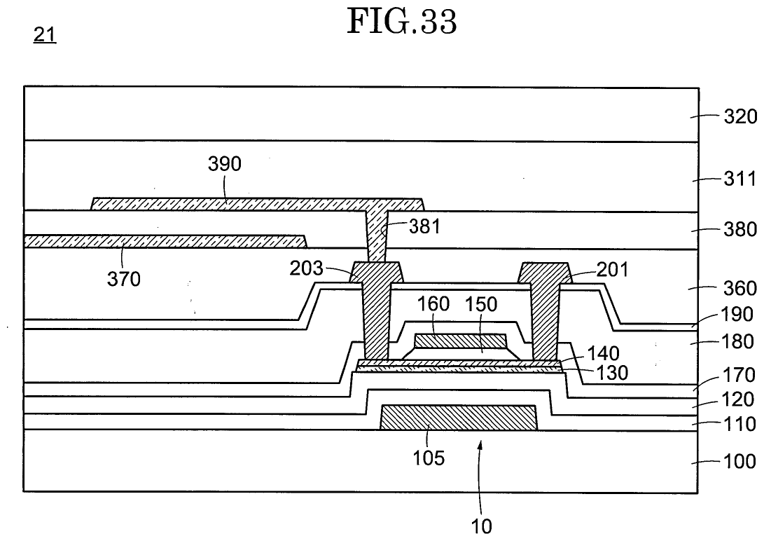

FIG. 33 is a schematic cross-sectional view showing a configuration of the pixel 21 of the display device 20 according to an embodiment of the present invention. As shown in FIG. 33, the display device 20 is a display device in which the semiconductor device 10 is arranged in the pixel 21. Although a configuration in which the semiconductor device 10 is used for the pixel circuit 301 is exemplified in the present embodiment, the semiconductor device 10 may be used for a peripheral circuit including the source driver circuit 302 and the gate driver circuit 303. In the following description, since the configuration of the semiconductor device 10 is the same as the configuration shown in FIG. 1 of the first embodiment, detailed descriptions thereof will be omitted.

An insulating layer 360 is arranged on the source wiring 201 and the drain wiring 203. A common electrode 370 arranged in common to the plurality of pixels is arranged on the insulating layer 360. An insulating layer 380 is arranged on the common electrode 370. An opening 381 is arranged in the insulating layers 360 and 380. A pixel electrode 390 is arranged on the insulating layer 380 and inside the opening 381. The pixel electrode 390 is connected to the drain wiring 203.

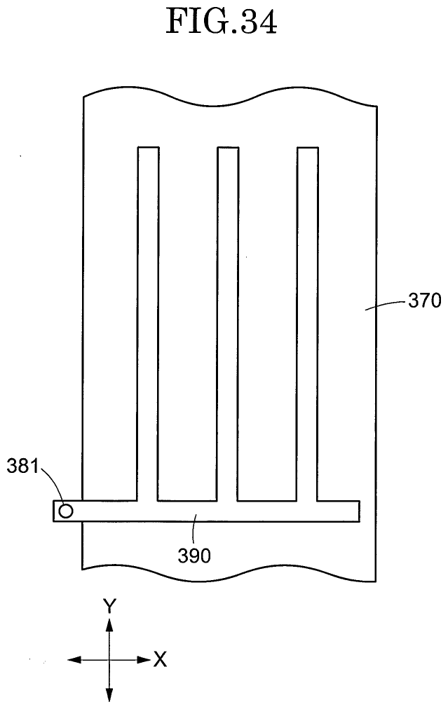

FIG. 34 is a schematic plan view showing a configuration of the pixel electrode 390 and the common electrode 370 of the display device 20 according to an embodiment of the present invention. As shown in FIG. 34, the common electrode 370 is composed of a flat plate-like conductive layer. The pixel electrode 390 is composed of a comb-shaped conductive layer in which a portion extending in the direction X and a portion extending in the direction Y are combined. The portion extending in the direction Y is composed of a plurality of linear electrodes, and is connected to the portion extending in the direction X.

The common electrode 370 has an overlapping region overlapping the pixel electrode 390 and a non-overlapping region not overlapping the pixel electrode 390 in a plan view. When a voltage is supplied between the pixel electrode 390 and the common electrode 370, an electric field in the transverse direction is generated from the pixel electrode 390 in the overlapping region towards the common electrode 370 in the non-overlapping region. When liquid crystal molecules contained in the liquid crystal element 311 are operated by the electric field in the transverse direction, a gradation of the pixel is determined.

### Seventh Embodiment

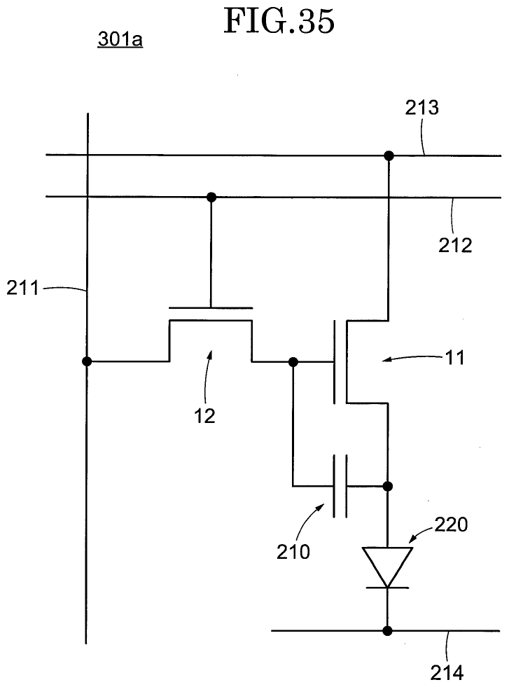

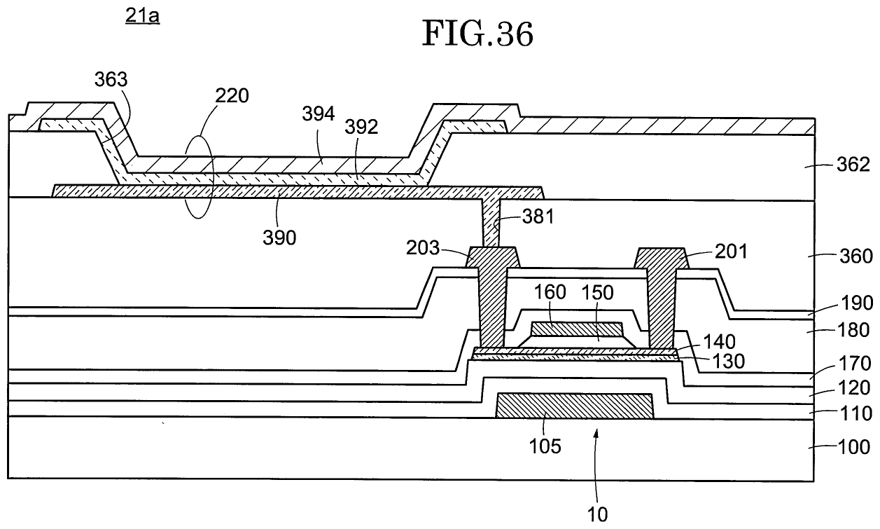

The display device 20 using a semiconductor device according to an embodiment of the present invention will be described with reference to FIG. 35 and FIG. 36. A configuration in which the semiconductor device 10 described in the first embodiment is applied to a circuit of an organic EL display device will be described in the embodiment described below. However, the present invention is not limited to this example, and the semiconductor device of any of the second to fourth embodiments may be applied to the circuit of the organic EL display device. Since the entire configuration and the circuit configuration of the display device 20 of the present embodiment are the same as those shown in FIG. 30 and FIG. 31, descriptions thereof will be omitted.

### [Pixel Circuit of Display Device]

FIG. 35 is a circuit diagram showing a configuration of a pixel circuit 301a of the display device 20 according to an embodiment of the present invention. As shown in FIG. 35, the pixel circuit 301a includes elements such as a drive transistor 11, a select transistor 12, a storage capacitor 210, and a light-emitting element 220.

The drive transistor 11 and the select transistor 12 have the same configuration as that of the semiconductor device 10. A source wiring of the select transistor 12 is connected to a data signal line 211 and a gate wiring of the select transistor 12 is connected to a scan signal line 212. A source wiring of the drive transistor 11 is connected to an anode power line 213, and a drain wiring of the drive transistor 11 is connected to one end of the light-emitting element 220. The other end of the light-emitting element 220 is connected to a cathode power line 214. A gate wiring of the drive transistor 11 is connected to a drain wiring of the select transistor 12. The storage capacitor 210 is connected to the gate wiring and the drain wiring of the drive transistor 11. A gradation signal that determines an emission intensity of the light-emitting element 220 is supplied to the data signal line 211. A signal that selects a pixel row to which the gradation signal is written is supplied to the scan signal line 212.

### [Cross-Sectional Structure of Display Device]

FIG. 36 is a schematic cross-sectional view showing a configuration of a pixel 21a of the display device 20 according to an embodiment of the present invention. A configuration of the pixel 21a shown in FIG. 36 is similar to the configuration of the pixel 21 shown in FIG. 33, but the pixel 21 and the pixel 21a are different from each other in the configuration above the insulating layer 360. Hereinafter, among the configuration of the pixel 21a shown in FIG. 36, the same configuration as that of the pixel 21 shown in FIG. 33 will be omitted, and differences between the two will be described.

As shown in FIG. 36, the pixel 21a has the pixel electrode 390, a light-emitting layer 392, and a common electrode 394 above the insulating layer 360. The light-emitting element 220 is composed of the pixel electrode 390, the light-emitting layer 392, and the common electrode 394. The pixel electrode 390 is arranged on the insulating layer 360 and inside the opening 381. In this case, an insulating layer 362 is called a bank, a rib, or the like, and has a function of defining a light-emitting region. The insulating layer 362 is arranged on the pixel electrode 390. An opening 363 is arranged in the insulating layer 362. The opening 363 corresponds to the light-emitting region. The light-emitting layer 392 and the common electrode 394 are arranged on the pixel electrode 390 exposed by the opening 363. The pixel electrode 390 and the light-emitting layer 392 are arranged separately for each pixel 21a. On the other hand, the common electrode 394 is arranged in common to a plurality of pixels 21a. Different materials are used for the light-emitting layer 392 depending on the display color of the pixel 21a.

### Eighth Embodiment

A configuration in which the semiconductor device 10 described in the first embodiment is applied to a liquid crystal display device and an organic EL display device, respectively, has been exemplified in the sixth embodiment and the seventh embodiment. However, the semiconductor device 10 described in the first embodiment may be applied to a display device (for example, a self-luminous display device other than organic EL display device or an electronic paper display device) other than these display devices. In addition, the semiconductor device 10 can be applied from a medium-sized display device to a large-sized display device without any particular limitation.

Each semiconductor device described in the second embodiment to the fifth embodiment may be applied to these display devices and are not limited to the semiconductor device 10 described in the first embodiment.

### EXAMPLES

### [Structure of Semiconductor Device]

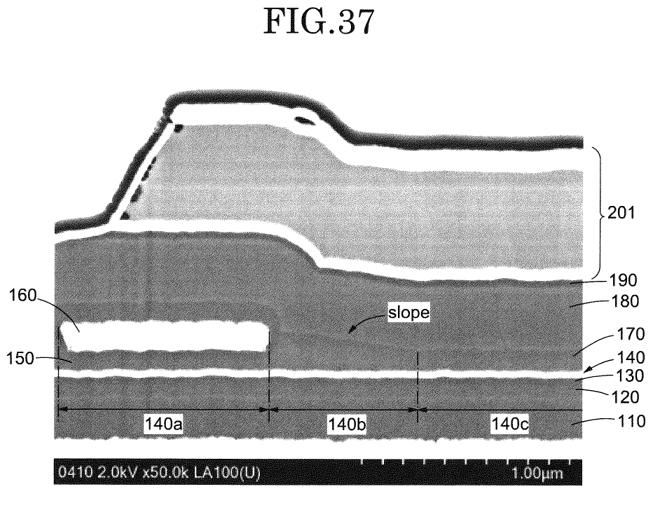

FIG. 37 is a drawing-substitute photograph showing a cross-sectional configuration of a semiconductor device according to an embodiment of the present invention. Specifically, FIG. 37 is a cross-sectional SEM photograph taken with respect to the semiconductor device 10 of the first embodiment actually manufactured. The reference signs shown in FIG. 37 correspond to the reference signs used in the semiconductor device 10 shown in FIG. 1. In addition, “Slope” in the drawings refers to an inclined surface formed on the upper surface of the insulating layer 170. In FIG. 37, since the gate insulating layer 150 and the insulating layer 170 are stacked above the LDD region 140b, the thickness is larger than the thickness of the insulating layer 170 arranged above the conductive region 140c. In addition, since the upper surface of the insulating layer 170 is an inclined surface, it can be seen that the upper surface of the gate insulating layer 150 corresponding to the non-overlapping region 150b is also an inclined surface.

### [Electrical Characteristics of Semiconductor Device]

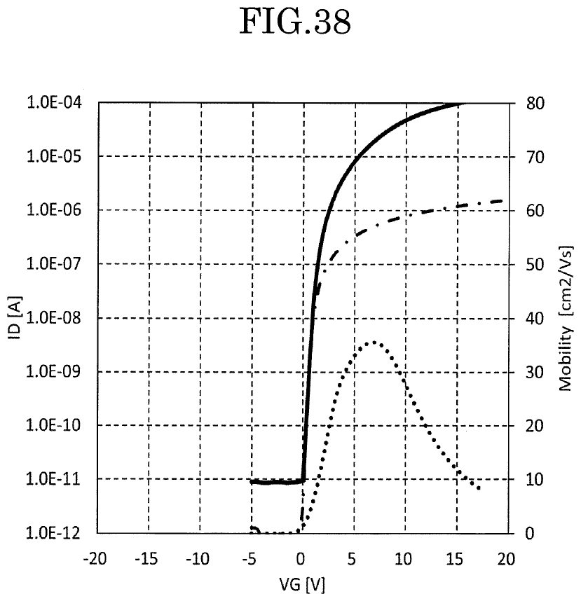

FIG. 38 is a diagram showing electrical characteristics of the semiconductor device 10 according to an embodiment of the present invention. Specifically, FIG. 38 shows ID-VG characteristics of the semiconductor device 10 with a channel length of 2 μm.

The measurement conditions of the electrical characteristics shown in FIG. 38 are as follows.
Size of the channel region: W/L=3 μm/2 μm
Source-drain voltage: 0.1 V, 10 V
Gate voltage: −5 V to +20 V
Measurement environment: room temperature, dark room

In FIG. 38, the ID-VG characteristics (electric characteristics indicating a change in the drain current with respect to the gate voltage) and the field-effect mobility (μsat) at the saturation region are shown as the electric characteristics of the semiconductor device. In the graph shown in FIG. 38, the vertical axis representing the drain current (ID) is shown on the left side of the graph. In addition, the vertical axis representing the field-effect mobility in the saturation region calculated from the drain current is shown on the right side of the graph. The horizontal axis represents the gate voltage (VG) supplied to the semiconductor device 10. In FIG. 38, the ID-VG characteristic indicated by a solid line is a characteristic when the source-drain voltage is 10 V, and the ID-VG characteristic indicated by a dashed-dotted line is a characteristic when the source-drain voltage is 0.1 V. In addition, the field-effect mobility in the saturation region is indicated by a dotted line.

As shown in FIG. 38, the ID-VG characteristic in the semiconductor device 10 of the first embodiment shows a so-called normally-off characteristic in which the drain current ID starts to flow when the gate voltage VG is substantially 0 V. The drain current is very stable, since it can be obtained sufficiently even if the source-drain voltage is 0.1 V or 10 V. The value of the field-effect mobility obtained from the electrical characteristics shown in FIG. 38 was 36.7 cm²/Vs. Although the ID-VG characteristics shown in FIG. 38 show an example in which the channel length is 2 μm, good electrical characteristics are obtained even in the semiconductor device 10 with a channel length of 1 μm.

As described above, it has been found that the semiconductor device 10 of the first embodiment has a high field-effect mobility without shifting the threshold voltage even when the channel length is small, such as 1 to 2 μm. In addition, it was confirmed that the semiconductor device 10 was capable of outputting a sufficiently on-state current despite having the LDD region 140b and had both excellent electrical characteristics and high reliability.

### Explanation of Experimental Data

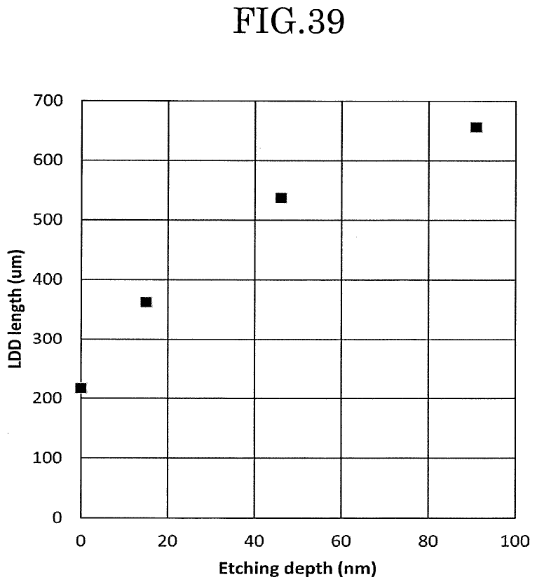

FIG. 39 is a graph showing a relationship between an amount of over-etching (referred to as “Etching depth” in the figure) during etching of the gate insulating layer 150 and the length of the LDD region 140b (referred to as “LDD length” in the figure). In this case, the “amount of over-etching” means a depth of the insulating layer 120 that is removed by etching that is continued after part of the oxide semiconductor layer 140 (the region used as the conductive region 140c) is exposed during etching of the gate insulating layer 150. In other words, the “amount of over-etching” can also be said to be a height of the step 121 shown in FIG. 1.

In FIG. 39, the horizontal axis represents the depth of the insulating layer 120 etched by over-etching, and the vertical axis represents the length of the LDD region 140b (ΔL). The measured value when the etching depth is 0 nm corresponds to the measured value when the upper surface of part of the oxide semiconductor layer 140 is exposed. The graph shown in FIG. 39 shows the length of the LDD region 140b when the etching process is performed under the following conditions when both the thickness of the insulating layer 120 and the thickness of the gate insulating layer 150 are 100 nm.

Condition 1: the gate insulating layer 150 is etched to a depth of 50 nm from the upper surface.

Condition 2: the gate insulating layer 150 is etched to a depth of 100 nm from the upper surface.

Condition 3: the gate insulating layer 150 is etched to a depth of 100 nm from the upper surface and the insulating layer 120 is etched to a depth of 50 nm from the upper surface.

Condition 4: the gate insulating layer 150 is etched to a depth of 100 nm from the upper surface and the insulating layer 120 is etched to a depth of 100 nm from the upper surface.

In the graph shown in FIG. 39, the etching depths of 0 nm, 15 nm, 46 nm, and 91 nm correspond to Condition 1, Condition 2, Condition 3, and Condition 4, respectively. In addition, Condition 2 corresponds to a timing at which the gate insulating layer 150 above the oxide semiconductor layer 140 is just eliminated, but the etching depth of the insulating layer 120 is 15 nm. This is probably due to the fact that the etching process of the gate insulating layer 150 is controlled using time, resulting in some errors. Conditions 3 and 4 also include some errors due to time control.

As shown in FIG. 39, it was confirmed that the length of the LDD region 140b also tended to increase as the etching depth of the insulating layer 120 increased. Specifically, it was confirmed that there was a nearly linear relationship between the etching depth of the insulating layer 120 and the length of the LDD region 140b. This means that the length of the non-overlapping region 150b of the gate insulating layer 150 changes linearly with the change in etching time in the etching process of the gate insulating layer 150. That is, it was found that the length of the LDD region 140b formed in the oxide semiconductor layer 140 can be reproducibly controlled by controlling the etching time of the gate insulating layer 150.

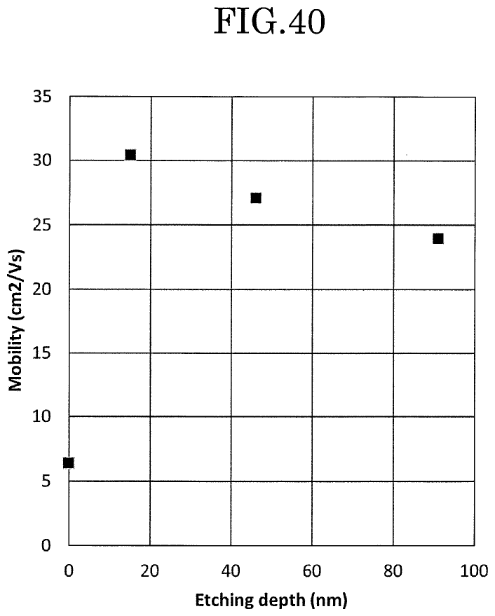

FIG. 40 is a graph showing a relationship between an amount of over-etching during etching of the gate insulating layer 150 and the field-effect mobility (referred to as “Mobility” in the figure). In FIG. 40, the horizontal axis represents the depth of the insulating layer 120 etched by over-etching, and the vertical axis represents the field-effect mobility. As described in the first embodiment, the “field-effect mobility” shown in FIG. 40 is the field-effect mobility in the saturation region of the semiconductor device 10. In the experiment shown in FIG. 40, the field-effect mobility is measured for each of Conditions 1 to 4 described above.

As shown in FIG. 40, the field-effect mobility is extremely low under Condition 1 (etching depth is 0 nm). The gate insulating layer 150 remains on the oxide semiconductor layer 140 and the upper surface of the oxide semiconductor layer 140 is not exposed in Condition 1. Therefore, it is presumed that hydrogen was not sufficiently supplied to a portion of the oxide semiconductor layer 140 due to the remaining gate insulating layer 150, resulting in insufficient formation of the conductive region 140c. Therefore, in Condition 1, it is presumed that a sufficient on-state current cannot be obtained when the semiconductor device 10 is driven, which leads to a decrease in the field-effect mobility.

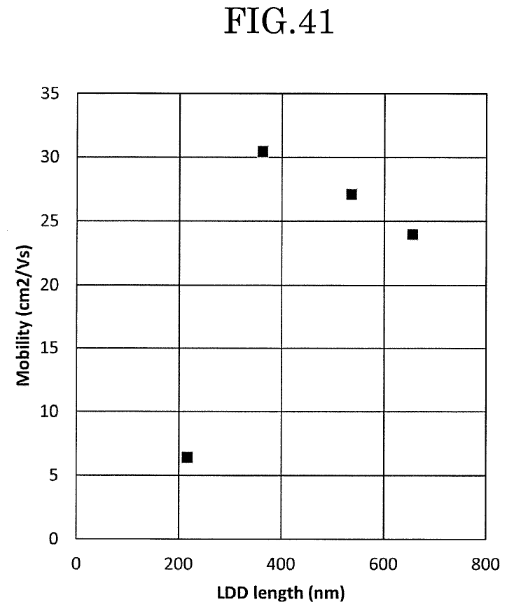

On the other hand, a field-effect mobility exceeding 30 cm²/Vs was obtained under Condition 2 (etching depth is 15 nm). In addition, the field-effect mobility tended to decrease as the etching depth of the insulating layer 120 increased. As shown in FIG. 39, the etching depth of the insulating layer 120 is approximately proportional to the length of the LDD region 140b. Therefore, it can be said that the decrease in the field-effect mobility shown in FIG. 39 is caused by the increase in the LDD region 140b. Thus, the relationship between the LDD region 140b and the field-effect mobility in the saturation region of the semiconductor device 10 is shown in FIG. 41.

FIG. 41 is a graph showing a relationship between the length of the LDD region 140b and the field-effect mobility. In FIG. 41, the horizontal axis represents the length of the LDD region 140b, and the vertical axis represents the field-effect mobility. The “field-effect mobility” shown in FIG. 41 is also the field-effect mobility in the saturation region of the semiconductor device 10. As shown in FIG. 41, a decrease in the field-effect mobility is observed as the length of the LDD region 140b increases, except for the case of Condition 1 (the case where the length of the LDD region 140b is about 217 nm). That is, the results shown in FIG. 40 and FIG. 41 indicate that the LDD region 140b formed in the semiconductor device 10 effectively functions as a resistance component. In addition, it was found from the graph shown in FIG. 41 that practical electrical characteristics (specifically, field-effect mobility) can be obtained in a range where the length of the LDD region 140b is 300 nm or more.

The above experimental data confirmed that the non-overlapping region 150b of the gate insulating layer 150 included in the semiconductor device of the above-described embodiments can form the LDD region 140b that effectively functions as a resistance component. In addition, it has been found that the semiconductor device of the above-described embodiments exhibits a high field-effect mobility even if it has an LDD region. As described above, the semiconductor device of the embodiments has both excellent electrical characteristics and high reliability.

Each of the embodiments described above as the embodiment of the present invention can be appropriately combined as long as no contradiction is caused. Further, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first insulating layer;
an oxide semiconductor layer having a polycrystalline structure on the first insulating layer;
a gate insulating layer on the oxide semiconductor layer;
a gate wiring on the gate insulating layer; and
a second insulating layer on the gate wiring, wherein
the oxide semiconductor layer has a first region, a second region and a third region aligned toward a first direction,
the first region overlaps the gate insulating layer and the gate wiring,
the third region is in contact with the second insulating layer, and
a distance from a top surface of the second region to a top surface of the second insulating layer is longer than a distance from a top surface of the third region to the top surface of the second insulating layer.

2. The semiconductor device according to claim 1, wherein
the second region is in contact with the gate insulating layer and does not overlap the gate wiring.

3. The semiconductor device according to claim 1, wherein
a top surface of the second insulating layer on the second region is inclined with respect to the top surface of the second region.

4. The semiconductor device according to claim 3, wherein
the inclination angle of the top surface of the second insulating layer with respect to the top surface of the second region is more than 5 degrees and less than 20 degrees.

5. The semiconductor device according to claim 1, wherein
a top surface of the gate insulating layer on the second region is inclined with respect to the top surface of the second region.

6. The semiconductor device according to claim 1, wherein
a length of the second region in the first direction is more than 0.3 μm and less than 1.0 μm.

7. The semiconductor device according to claim 1, wherein
a top surface of the second insulating layer within a predetermined distance from an edge of the portion of the gate wiring not overlapping the oxide semiconductor layer is inclined with respect to a top surface of the gate wiring.

8. The semiconductor device according to claim 7, wherein
the predetermined distance is more than 0.3 μm and less than 1.0 μm.

9. The semiconductor device according to claim 1, wherein
the second insulating layer includes a silicon oxide layer.

10. The semiconductor device according to claim 1, wherein
the first region is a channel region, and
the second region is a region of lower resistance than the channel region.

11. The semiconductor device according to claim 10, wherein
the third region is a region of lower resistance than the second region.

12. The semiconductor device according to claim 1, further comprising a metal oxide layer between the first insulating layer and the oxide semiconductor layer.

13. The semiconductor device according to claim 12, wherein
the metal oxide layer and the oxide semiconductor layer have the same pattern shape.

14. The semiconductor device according to claim 1, wherein
the oxide semiconductor layer contains at least two or more metallic elements including indium, and
a ratio of indium to the at least two or more metallic elements is 50% or more.

15. A display device having a plurality of pixels, each of the plurality of pixels comprising the semiconductor device according to claim 1.
